(19) United States
(12) Patent Application Publication
(10) Pub. No.: US 2025/0164530 A1
(43) Pub. Date: May 22, 2025

(54) CURRENT SENSOR

(71) Applicant: Asahi Kasei Microdevices Corporation, Tokyo (JP)

(72) Inventor: Masaki TSUJIMOTO, Tokyo (JP)

(21) Appl. No.: 18/953,081

(22) Filed: Nov. 20, 2024

(30) Foreign Application Priority Data
Nov. 21, 2023 (JP) 2023-197572
Mar. 18, 2024 (JP) 2024-042002
Nov. 12, 2024 (JP) 2024-197108

(51) Int. Cl. G01R 15/20; G01R 19/00

(52) U.S. Cl. CPC G01R 15/202; G01R 19/0092

(57) ABSTRACT

A current sensor includes a first lead frame having a first terminal portion and a conductive portion coupled to the first terminal portion, wherein a measurement current measured by the at least one magnetoelectric conversion element flows through the first terminal portion and the conductive portion; and a signal processing IC that processes a signal output from the at least one magnetoelectric conversion element, arranged on a second surface side opposing a first surface of the conductive portion, having a circuit surface with the at least one magnetoelectric conversion element arranged thereon. The conductive portion has a first corner between a first end surface opposing a side coupled to the first terminal portion and a second surface facing the signal processing IC, and a second corner between the first end surface and a first surface opposing the second surface facing the signal processing IC.

The contents of the following patent application(s) are incorporated herein by reference:
NO. 2023-197572 filed in JP on Nov. 21, 2023
NO. 2024-042002 filed in JP on Mar. 18, 2024
NO. 2024-197108 filed in JP on Nov. 12, 2024.

### BACKGROUND

### 1. Technical Field

The present invention relates to a current sensor.

### 2. Related Art

In Patent Document 1, a current sensor including a conductive wire that couples a magnetic sensor and a signal processing IC without crossing a primary conductor is disclosed.

### PRIOR ART DOCUMENTS

### Patent Document

Patent Document 1: Japanese Patent Application Publication No. 2018-036237

### BRIEF DESCRIPTION OF THE DRAWINGS

FIG. 1A is a schematic plan view of a current sensor according to a first embodiment as viewed from a top surface side (in a Z-axis direction).

FIG. 1B is an A-A line sectional view of the current sensor shown in FIG. 1A.

FIG. 1C is a schematic plan view of a current sensor according to a variant of the first embodiment as viewed from the top surface side (in the Z-axis direction).

FIG. 1D is an A-A line sectional view of the current sensor shown in FIG. 1C.

FIG. 2 shows an example of an enlarged drawing of an enclosed portion indicated by a sign 300 shown in FIG. 1B.

FIG. 3A shows an example of simulation results of electric field strength when a potential difference is provided between a terminal portion 142 and a terminal portion 152 in a structure where a first corner 1401 is not chamfered.

FIG. 3B shows an example of simulation results of an electric field when a potential difference is provided between the terminal portion 142 and the terminal portion 152 in the structure where the first corner 1401 is chamfered.

FIG. 4 shows an example of a relationship between a size of the chamfer and a maximum electric field.

FIG. 5A shows an example of a shape of the chamfer of the first corner 1401.

FIG. 5B shows an example of a shape of the chamfer of the first corner 1401.

FIG. 5C shows an example of a shape of the chamfer of the first corner 1401.

FIG. 6A shows an example of simulation results of equivalent stress in a structure where a third corner 1403 is not chamfered.

FIG. 6B shows an example of simulation results of equivalent stress in a structure where the third corner 1403 is chamfered.

FIG. 7 shows an example of a relationship between a size of the chamfer and a magnitude of the equivalent stress.

FIG. 8A shows an example of simulation results of thermal stress in a structure where a fifth corner 1405 and a seventh corner 1501 are not chamfered.

FIG. 8B shows an example of simulation results of thermal stress in a structure where the fifth corner 1405 and the seventh corner 1501 are chamfered.

FIG. 9 shows an example of an enlarged drawing in a vicinity of a conductive portion of a current sensor according to a second embodiment.

FIG. 10 shows an example of an enlarged drawing of the vicinity of the conductive portion of a current sensor according to a third embodiment.

FIG. 11 shows a schematic plan view of a current sensor according to a fourth embodiment as viewed from a top surface side (in a Z-axis direction).

FIG. 12 shows an example of an enlarged drawing of the vicinity of the conductive portion of the current sensor according to the fourth embodiment.

FIG. 13A is a schematic plan view of a current sensor according to a fifth embodiment as viewed from a top surface side (in the Z-axis direction).

FIG. 13B is an A-A line sectional view of the current sensor shown in FIG. 12A.

FIG. 13C is a B-B line sectional view of the current sensor shown in FIG. 13A.

FIG. 14A is a schematic plan view of a current sensor according to a variant of the embodiment shown in FIG. 13A as viewed from the top surface side (in the Z-axis direction).

FIG. 14B is an A-A line sectional view of the current sensor shown in FIG. 14A.

FIG. 15 shows an example of an enlarged drawing of an enclosed portion indicated by a sign 300 shown in FIG. 13B.

FIG. 16A shows an example of a shape of a chamfer of a second corner.

FIG. 16B shows an example of a shape of the chamfer of the second corner.

FIG. 16C shows an example of a shape of the chamfer of the second corner.

FIG. 17A shows an example of simulation results of thermal stress when the current sensor is placed in an environment with a minimum temperature of −65° C., which is required for a durability test in a structure where the second corner is not chamfered.

FIG. 17B shows an example of simulation results of thermal stress when the current sensor is placed in an environment with a minimum temperature of −65° C., which is required for a durability test in a structure where the second corner is chamfered.

FIG. 18A is a cross-sectional view of a current sensor according to a sixth embodiment as viewed from an X-axis direction.

FIG. 18B is a cross-sectional view of the current sensor according to the sixth embodiment as viewed from a Y-axis direction.

FIG. 19 shows an example of an enlarged drawing of an enclosed portion indicated by a sign 300 shown in FIG. 18A.

FIG. 20 shows an example of a shape of a chamfer of a fourth corner.

### DESCRIPTION OF EXEMPLARY EMBODIMENTS

The present invention will be described below through embodiments of the invention, but the following embodiments do not limit the invention according to the claims. In addition, not all of the combinations of features described in the embodiments are essential to the solutions of the invention.

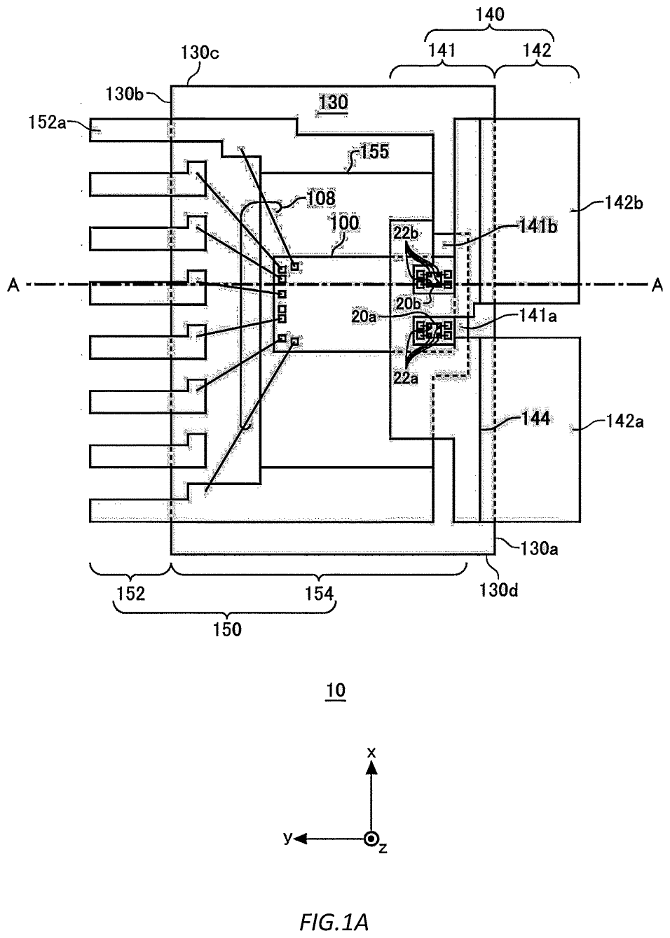

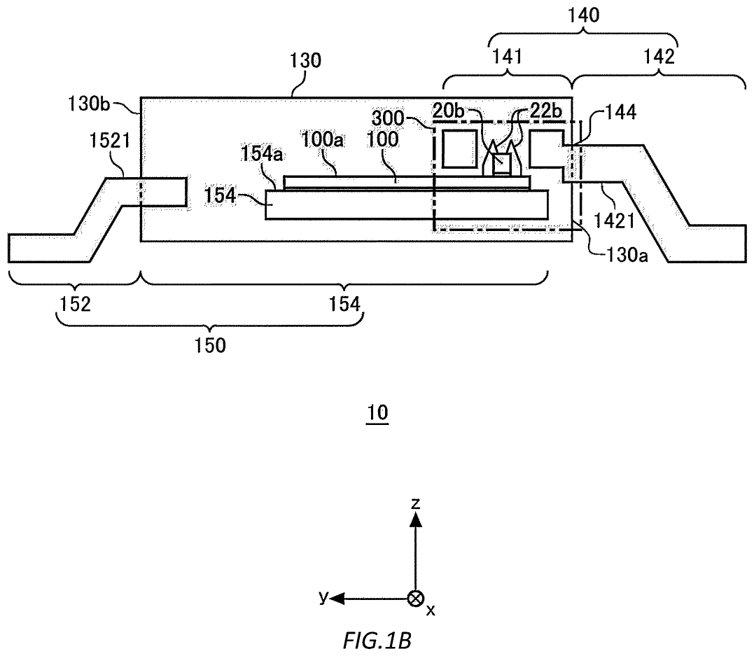

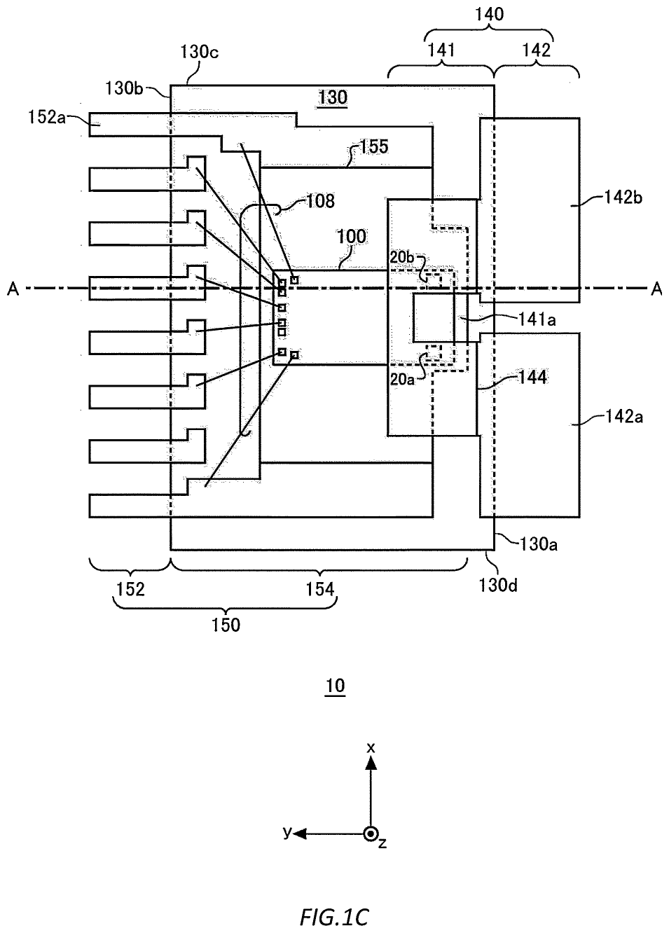

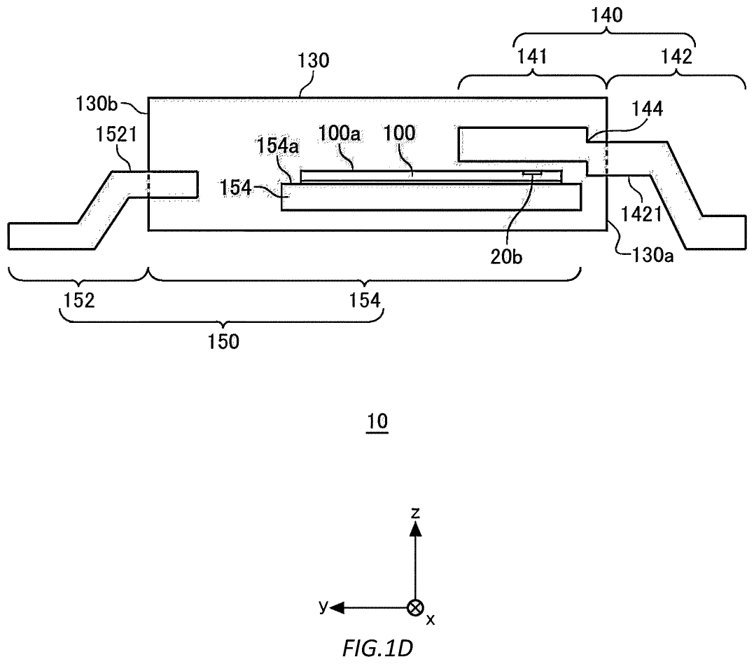

FIG. 1A and FIG. 1B show the internal configuration of a semiconductor package that functions as a current sensor 10 according to the first embodiment. FIG. 1A is a schematic plan view as viewed from the top surface side (in the Z-axis direction) of the current sensor 10 according to the first embodiment. FIG. 1B is an A-A line sectional view of the current sensor 10 shown in FIG. 1A.

For the coordinate, in FIG. 1A, the X-axis direction is defined as a direction from bottom to top and parallel to the sheet of paper, the Y-axis direction is defined as a direction from right to left and parallel to the sheet of paper, and the Z-axis direction is defined as a direction from back to front and perpendicular to the sheet of paper. Any one axis among the X axis, Y axis, and the Z axis is orthogonal to another axis.

The current sensor 10 comprises a signal processing IC 100, a magnetoelectric conversion element 20a, a magnetoelectric conversion element 20b, a lead frame 140 on the current conductor side, a lead frame 150 on the signal terminal side, and a sealing portion 130.

The lead frame 140 includes a conductive portion 141 and a terminal portion 142. The terminal portion 142 includes a pair of terminals 142a, 142b. The conductive portion 141 is sealed inside the sealing portion 130, partially enclosing the magnetoelectric conversion element 20a and the magnetoelectric conversion element 20b. A measurement current flows through the terminal portion 142 and the conductive portion 141. The pair of terminals 142a, 142b are configured to be physically integrated with the conductive portion 141, exposing to the outside of the sealing portion 130. The lead frame 140 is an example of a first lead frame.

The lead frame 140 may be manufactured by using singulated metal parts by grouping a plurality of metal plates, without a need to be manufactured in a form of composing the conductive portion 141 and the terminal portion 142.

The lead frame 150 includes a support portion 154 and a terminal portion 152. The terminal portion 152 includes a plurality of terminals 152a. The support portion 154 is sealed inside the sealing portion 130, and supports the signal processing IC 100. Some terminals 152a of the plurality of terminals 152a are configured to be physically integrated with the support portion 154. At least a part of each of the plurality of terminals 152a is exposed to the outside of the sealing portion 130. The lead frame 150 is an example of a second lead frame. The lead frame 140 and the lead frame 150 may be composed of a conductor material principally made of copper. The support portion 154 may be composed of an insulating member such as a metal plate separate from the lead frame 150, a plate composed of semiconductor or die-attach film.

The pair of terminals 142a, 142b and the plurality of terminals 152a are arranged to oppose each other via the signal processing IC 100 in a direction (Y-axis direction) that intersects with the thickness direction (Z-axis direction) of the signal processing IC 100. The direction intersecting the thickness direction may be a direction along a plane (XY plane) orthogonal to the thickness direction. The pair of terminals 142a, 142b are exposed from a side surface 130a of the sealing portion 130. The plurality of terminals 152a are exposed from a side surface 130b, which is a side opposite to the side surface 130a of the sealing portion 130. As shown in FIG. 1B, the pair of terminals 142a, 142b and the plurality of terminals 152a may protrude from different heights from each other in the thickness direction of the sealing portion 130 of the side surface 130a and side surface 130b, which oppose each other, of the sealing portion 130, toward the outside. A surface 1521 on a side identical to the surface 100a of the signal processing IC 100 of the plurality of terminals 152a and a surface 1421 on a side identical to the surface opposing the surface 100a of the signal processing IC 100 of the pair of terminals 142a, 142b may be in positions at a height identical to each other in the thickness direction of the sealing portion 130 (Z-axis direction). Alternatively, the surface 1521 of the plurality of terminals 152a may be located downwardly in the thickness direction of the sealing portion 130 when compared to the surface 1421 of the pair of terminals 142a, 142b.

That is, a height in the thickness direction of the sealing portion 130 (Z-axis direction) of the surface 1521 on the side identical to the surface 100a of the signal processing IC 100 of the plurality of terminals 152a in a position intersecting the side surface 130a of the sealing portion 130 may be identical to a height in the thickness direction of the sealing portion 130 (Z-axis direction) of the surface 1421 on a side identical to the surface opposing the surface 100a of the signal processing IC 100 of the pair of terminals 142a, 142b in the position intersecting the side surface 130b of the sealing portion 130. Alternatively, the height in the thickness direction of the sealing portion 130 (Z-axis direction) of the surface 1521 of the plurality of terminals 152a in the position intersecting the side surface 130a of the sealing portion 130 may be located downwardly when compared to the height in the thickness direction of the sealing portion 130 (Z-axis direction) of the surface 1421 of the pair of terminals 142a, 142b in the position intersecting the side surface 130b of the sealing portion 130.

The pair of terminals 142a, 142b protrude from the side surface 130a to the negative side in the Y-axis direction, and are further bent to the negative side in the Z-axis direction. The plurality of terminals 152a protrude from the side surface 130b to the positive side in the Y-axis direction, and are further bent to the negative side in the Z-axis direction. The pair of terminals 142a, 142b may protrude from the side surface 130a to the negative side in the Y-axis direction, and may further be bent to the positive side in the Z-axis direction. The plurality of terminals 152a may protrude from the side surface 130b toward the positive side in the Y-axis direction, and may further be bent to the positive side in the Z-axis direction. The pair of terminals 142a, 142b, and the plurality of terminals 152a may not be bent. That is, the pair of terminals 142a, 142b may protrude from the side surface 130a to the negative side in the Y-axis direction, and not be bent to the positive side nor the negative side in the Z-axis direction. The plurality of terminals 152a may protrude from the side surface 130b toward the positive side in the Y-axis direction, and may not be further bent to the positive side nor the negative side in the Z-axis direction.

The support portion 154 may have a stepped portion 155 in which the portion supporting the signal processing IC 100 is dented in a direction away from the conductive portion 141 (toward the bottom surface side of the sealing portion 130) in the thickness direction (Z-axis direction). The stepped portion 155 is an example of a first stepped portion. The signal processing IC 100 may be fixed via an adhesive layer on the surface 154a of a portion that supports the signal processing IC 100. The adhesive layer may be a die-attach film. The lead frame 140 has a stepped portion 144 that protrudes in a direction in which an opposing portion that faces the signal processing IC 100 moves away from the signal processing IC 100 in the thickness direction. The stepped portion 144 is an example of a second stepped portion. The stepped portion 155 and the stepped portion 144 may be formed through half blanking processing in the lead frame 150 and the lead frame 140. In this case, there exists a sheared surface in the stepped portion 155 and the stepped portion 144.

The conductive portion 141 has two slit portions 141a, 141b. The magnetoelectric conversion element 20a is partially enclosed by the conductive portion 141 by being arranged inside the slit portion 141a in a planar view. The magnetoelectric conversion element 20b is partially enclosed by the conductive portion 141 by being arranged in the slit portion 141b in a planar view. The magnetoelectric conversion elements 20a, 20b may be fixed to the circuit surface of the signal processing IC 100 by die bonding and electrically coupled to the signal processing IC 100 by wire bonding. That is, the magnetoelectric conversion elements 20a, 20b may be electrically coupled to the signal processing IC 100 via a plurality of wires 22a, 22b. The magnetoelectric conversion elements 20a, 20b may be electrically coupled to the signal processing IC 100 by flip chip bonding. The magnetoelectric conversion elements 20a, 20b output a signal processed by the signal processing IC 100 to the signal processing IC 100. The magnetoelectric conversion elements 20a, 20b may be configured to be separate from the signal processing IC 100. That is, the magnetoelectric conversion elements 20a, 20b may be composed of a chip separate from the chip composing the signal processing IC 100. The magnetoelectric conversion elements 20a, 20b may be built in the chip composing the signal processing IC 100.

The magnetosensitive surfaces of the magnetoelectric conversion elements 20a, 20b may be arranged in a position overlapping the side surface with the slit portions 141a, 141b provided thereon as viewed from the direction (X-axis direction or Y-axis direction) intersecting the thickness direction (Z-axis direction) of the magnetoelectric conversion elements 20a, 20b.

The signal processing IC 100 is electrically coupled to the plurality of terminals 152a via the wire 108. The wires 22a and 22b and the wire 108 may be formed of a conductor material containing Au, Ag, Cu, or Al as a main component.

The magnetoelectric conversion elements 20a, 20b may protrude from the surface 100a of the signal processing IC 100 so that the magnetosensitive surfaces of the magnetoelectric conversion elements 20a, 20b overlap the conductive portion 141 as viewed from the side surface. In this manner, the sensitivity of the magnetoelectric conversion elements 20a, 20b can be improved.

The magnetoelectric conversion elements 20a, 20b detect the magnetic field in a particular direction that changes according to the measurement current flowing through the conductive portion 141, and the signal processing IC 100 amplifies the signal according to the magnitude of the magnetic field to output the amplified signal via the terminal 152a. The magnetoelectric conversion elements 20a, 20b are composed of a compound semiconductor formed on a GaAs substrate, and may be chips cut out in a square or rectangular shape in a planar view from the Z-axis direction.

The magnetoelectric conversion elements 20a, 20b may have a substrate constituted by silicon or a compound semiconductor and a magnetoelectric conversion unit provided on the substrate. The thickness of the substrate is adjusted by grinding a surface on the negative side in the Z-axis direction. Since the magnetic field in the Z-axis direction is to be detected, for example, hall elements that detect the longitudinal magnetic field in the thickness direction of the conductive portion 141 are appropriate as the magnetoelectric conversion elements 20a, 20b. In addition, in a case where the magnetoelectric conversion elements 20a, 20b are arranged at positions where a magnetic field in any one axial direction on an XY plane is detected, for example, when the magnetoelectric conversion elements are arranged at positions where a magnetic field in the X-axis direction is detected, magneto-resistance elements or flux gate elements are suitable as the magnetoelectric conversion elements 20a, 20b. More specifically, the magnetoelectric conversion elements 20a, 20b may be arranged so as to overlap the conductor 141 in a planar view from the Z-axis direction. FIG. 1C and FIG. 1D show examples of the current sensor 10 in which the magnetoelectric conversion elements are arranged in positions for detecting a magnetic field in the X-axis direction. FIG. 1C shows an internal configuration of the semiconductor package that functions as a current sensor 10 according to a variant of the first embodiment. FIG. 1C is a schematic plan view as viewed from the top surface side of the current sensor 10 (in a Z-axis direction) according to the variant of the first embodiment. FIG. 1D is an A-A line sectional view of the current sensor 10 shown in FIG. 1C. In the current sensor 10 according to the variant of the first embodiment, the magnetoelectric conversion elements 20a, 20b are built in the chip composing the signal processing IC 100.

The signal processing IC 100 is a Large-scale Integration circuit (LSI). The signal processing IC 100 is a monolithic IC. More specifically, the signal processing IC 100 is a signal processing circuit formed of Si monolithic semiconductors formed on a Si substrate. The signal processing IC 100 has a circuit surface with the magnetoelectric conversion elements 20a, 20b arranged thereon. In the first embodiment, the circuit surface is the surface 100a equivalent to a top surface of the semiconductor package composing the signal processing IC 100. The surface 100a is an example of the first surface of the signal processing IC 100. The signal processing circuit processes output signals corresponding to the magnitudes of the magnetic field output from the magnetoelectric conversion elements 20a, 20b. The signal processing circuit corrects the measurement current flowing through the conductive portion 141 based on the output signal, and outputs an output signal showing an accurate current value via the terminal 152a. The signal processing circuit reduces a noise component included in the output signal of the magnetoelectric conversion element 20a and the output signal of the magnetoelectric conversion element 20b, based on a difference between the output signal of the magnetoelectric conversion element 20a and the output signal of the magnetoelectric conversion element 20b, amplifies the output signal of the magnetoelectric conversion element 20a and the output signal of the magnetoelectric conversion element 20b in which the noise component is reduced, calculates the current value of the measurement current based on the amplified output signal, and outputs the output signal indicating the current value.

The sealing portion 130 seals, with mold resin, the magnetoelectric conversion elements 20a, 20b, the conductive portion 141, the support portion 154, the signal processing IC 100, the wires 22a, 22b and the wire 108. The mold resin may be, for example, comprised of an epoxy-based thermally curable resin added with silica and formed into a semiconductor package by a transfer molding.

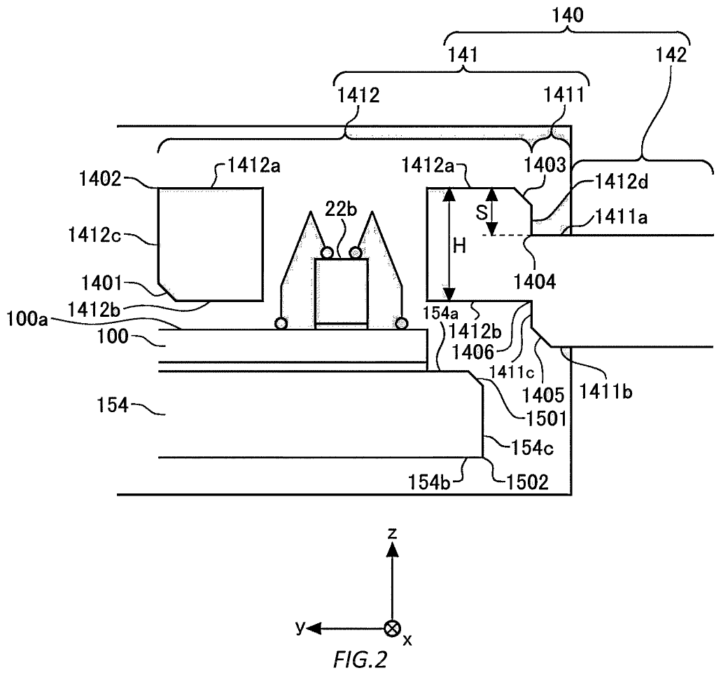

FIG. 2 shows an example of an enlarged drawing of an enclosed portion indicated by a sign 300 shown in FIG. 1B. The conductive portion 141 has a first portion 1411 coupled to the terminal portion 142, and a second portion 1412 arranged to face the surface 100a of the signal processing IC 100, shifted with respect to the first portion 1411 in a direction away from the surface 100a of the signal processing IC 100 in the thickness direction and coupled to the first portion 1411. The second portion 1412 is shifted with respect to the first portion 1411 by the half blanking processing of the conductive portion 141.

The second portion 1412 has a first corner 1401 between a first end surface 1412c opposing a side coupled to the terminal portion 142 and a second surface 1412b facing the signal processing IC 100, and a second corner 1402 between the first end surface 1412c and a first surface 1412a opposing the second surface 1412b facing the signal processing IC 100. The second portion 1412 has a third corner 1403 between a second end surface 1412d on a side coupled to the first portion 1411 and the first surface 1412a opposing the second surface 1412b facing the surface 100a of the signal processing IC 100. The first portion 1411 has a fifth corner 1405 between a third end surface 1411c on the side coupled to the second portion 1412 and the second surface 1411b on a side identical to the second surface 1412b of the second portion 1412.

The support portion 154 of the lead frame 150 has a seventh corner 1501 between the surface 154a that supports the signal processing IC 100 and a fourth end surface 154c on the terminal portion 142 side, and an eighth corner 1502 between the second surface 154b opposing the surface 154a that supports the signal processing IC 100 and the fourth end surface 154c.

Herein, each of the first corner 1401, the third corner 1403, the fifth corner 1405 and the seventh corner 1501 is a chamfered surface. An outer surface area of the first corner 1401 is greater than an outer surface area of the second corner 1402. The outer surface area of the first corner 1401 is an area of a chamfered surface. The outer surface area of the first corner 1401 is an outer surface area defined from a boundary between the second surface 1412b and the first corner 1401 to a boundary between the first end surface 1412c and the first corner 1401. The outer surface area of the second corner 1402 is an outer surface area defined from a boundary between the first end surface 1412c and the second corner 1402 to a boundary between the first surface 1412a and the second corner. The second corner 1402 may be approximately linear along the X-axis direction. The outer surface area of the second corner 1402 may be substantially zero.

An outer surface area of the third corner 1403 is greater than an outer surface area of a fourth corner 1404 between the second end surface 1412d of the second portion 1412 and a first surface 1411a of the first portion 1411 on a side identical to the first surface 1412a of the second portion 1412. The outer surface area of the third corner 1403 is an area of the chamfered surface. The outer surface area of the third corner 1403 is an outer surface area defined from a boundary between the first surface 1412a and the third corner 1403 to a boundary between the second end surface 1412d and the third corner 1403. The outer surface area of the fourth corner 1404 is an outer surface area defined from a boundary between the second end surface 1412d and the fourth corner 1404 to a boundary between the first surface 1411a and the fourth corner 1404. The fourth corner 1404 may be approximately linear along the X-axis direction. The outer surface area of the fourth corner 1404 may be substantially zero.

An outer surface area of the fifth corner 1405 is greater than an outer surface area of a sixth corner 1406 between a third end surface 1411c of the first portion 1411 and the second surface 1412b of the second portion 1412. The outer surface area of the fifth corner 1405 is an area of the chamfered surface. The outer surface area of the fifth corner 1405 is an outer surface area defined from a boundary between the third end surface 1411c and the fifth corner 1405 to a boundary between the fifth corner 1405 and the second surface 1411b. The outer surface area of the sixth corner 1406 is an outer surface area defined from a boundary between the second surface 1412b and the sixth corner 1406 to a boundary between the sixth corner 1406 and the third end surface 1411c. The sixth corner 1406 may be approximately linear along the X-axis direction. The outer surface area of the sixth corner 1406 may be substantially zero.

An outer surface area of the seventh corner 1501 is greater than an outer surface area of the eighth corner 1502. The outer surface area of the seventh corner 1501 is an area of the chamfered surface. The outer surface area of the seventh corner 1501 is an area of the chamfered surface. An outer surface area of the seventh corner 1501 is an outer surface area defined from a boundary between the surface 154a and the seventh corner 1501 to a boundary between the seventh corner 1501 and the fourth end surface 154c. The outer surface area of the eighth corner 1502 is an outer surface area defined from a boundary between the surface 154b and the eighth corner 1502 to a boundary between the eighth corner 1502 and the fourth end surface 154c. The eighth corner 1502 may be approximately linear along the X-axis direction. The outer surface area of the eighth corner 1502 may be substantially zero.

In this manner, by chamfering each of the first corner 1401, the third corner 1403, the fifth corner 1405 and the seventh corner 1501, electric field concentration and stress concentration in a vicinity of the corners can be suppressed, thereby the durability of the current sensor 10 can be improved. That is, the occurrence of withstand voltage defects due to the short distance between the signal processing IC 100 and the conductive portion 141 can be suppressed.

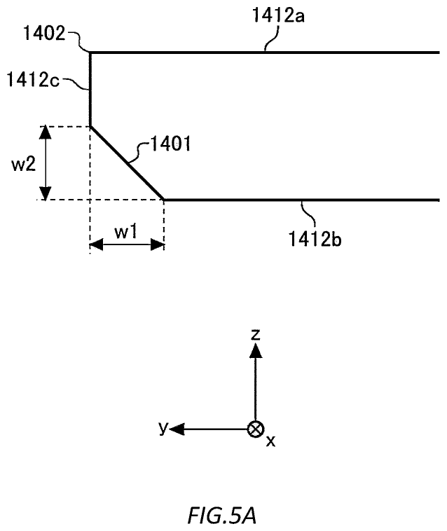

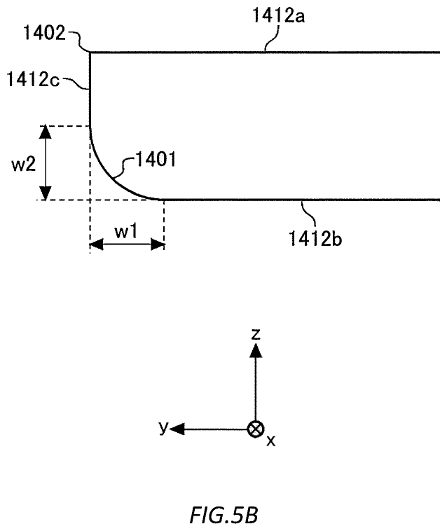

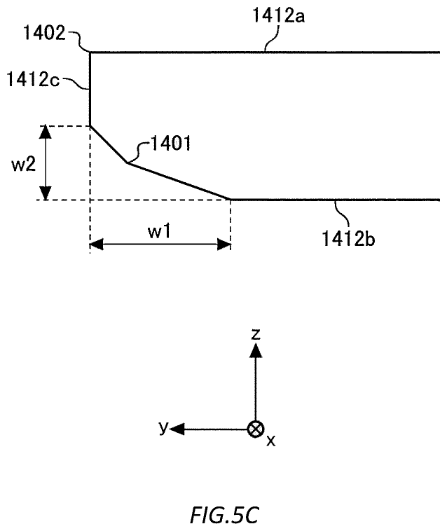

The shape of each chamfer of the first corner 1401, the third corner 1403, the fifth corner 1405 and the seventh corner 1501 may be any shape and may be composed of a plurality of surfaces obtained by combining with a plurality of abbreviated planes. The shape of the chamfer may consist of one plane of an abbreviated plane as shown in FIG. 5A, one plane of an R surface (curved surface) as shown in FIG. 5B, or two planes combined with two abbreviated planes as shown in FIG. 5C, which are described below. When the first corner 1401, the third corner 1403, the fifth corner 1405 and the seventh corner 1501 as shown in FIG. 5B are R surfaces, the outer surface areas of the first corner 1401, the third corner 1403, the fifth corner 1405, and the seventh corner 1501 are areas of the curved surface portions. Each boundary between surfaces adjacent to the first corner 1401, the third corner 1403, the fifth corner 1405 or the seventh corner 1501 is a portion where each curved surface starts.

The following is an explanation of the reason why each of the first corner 1401, the third corner 1403, the fifth corner 1405 and the seventh corner 1501 is chamfered to allow suppressing electric field concentration or stress concentration in the vicinity of the corner.

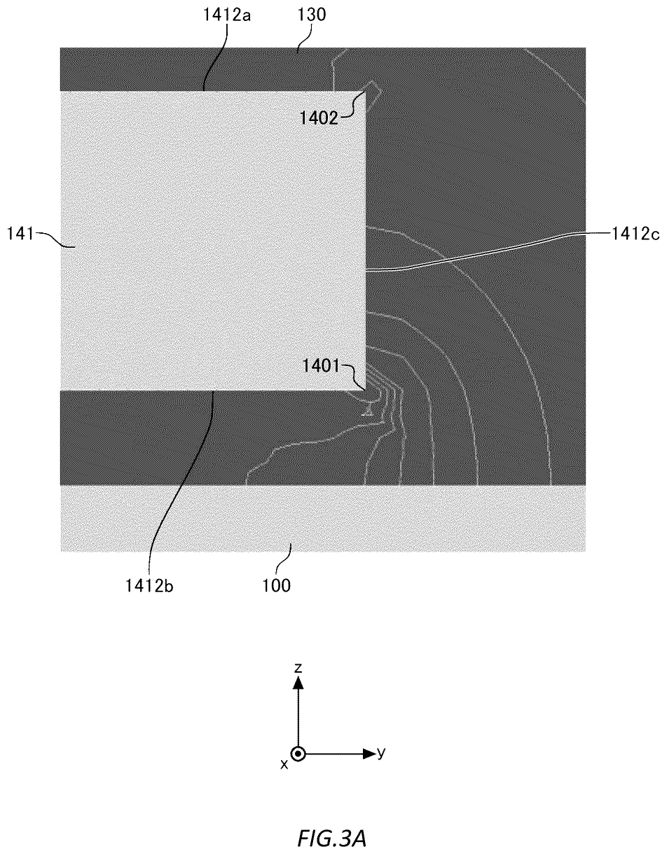

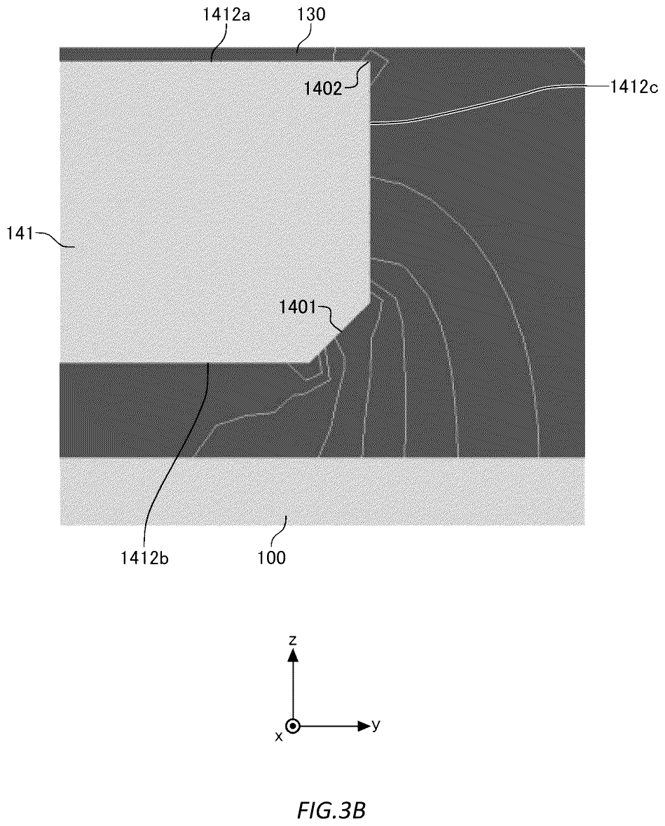

FIG. 3A shows an example of simulation results of electric field strength when a potential difference is provided between a terminal portion 142 and a terminal portion 152 in a structure where a first corner 1401 is not chamfered. The terminal portion 142 may be at a high voltage in the process of applying the current to-be-measured. FIG. 3B shows an example of simulation results of electric field strength when a potential difference is provided between the terminal portion 142 and the terminal portion 152 in the structure where the first corner 1401 is chamfered. FIG. 3A and FIG. 3B show contour plots of the electric field. Comparing FIG. 3A and FIG. 3B, it can be seen that the contour of the electric field shown in FIG. 3A is denser than the contour of the electric field shown in FIG. 3B in the vicinity of the first corner 1401. That is, it can be seen that the electric field is more likely to be concentrated in the vicinity of the first corner 1401 if not chamfered.

In a case of a structure where the lead frame 140 on the current conductor side and the lead frame 150 on the signal terminal side are stacked in the thickness direction, the portion where the electric field tends to concentrate most is the first corner 1401 of the second portion 1412 in the conductive portion 141 of the lead frame 140 on the current conductor side. Therefore, chamfering the first corner 1401 of the second portion 1412 can suppress electric field concentration and improve the durability of the current sensor 10.

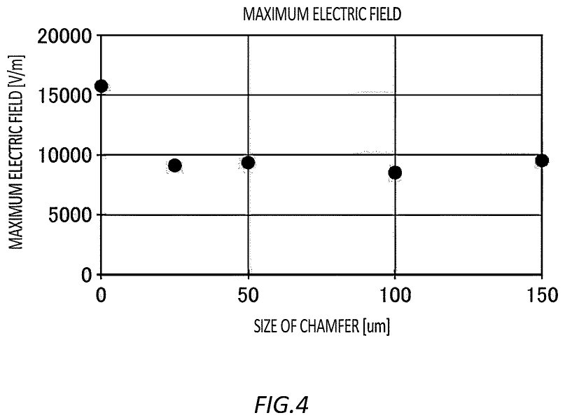

FIG. 4 shows an example of a relationship between a size of the chamfer and a maximum electric field. As shown in FIG. 4, even a chamfer of approximately 25 μm can significantly lower the maximum electric field.

The mold resin composing the sealing portion 130 contains a large amount of filler. The mold resin contains filler with a filler diameter (diameter) of 20 μm or greater, and the filler filling ratio is 60% or greater. The mode of diameter of the filler contained in the mold resin is approximately 20 μm. Then if there exists a sphere with a diameter of approximately 20 μm in three dimensions, the filler diameter is approximately 15 μm (20 μm×(√3/2)²), since the dimension drops to one dimension when viewed on the line segment of the chamfered portion. The filler then obstructs the path of the discharge when the discharge is about to occur, thereby making it more difficult for the discharge to occur. Therefore, if the width of the chamfered surface is equal to or greater than the filler diameter, the possibility of filler being present in the chamfered portion is very high, which is capable of making it difficult for the discharge to occur. The simulation results shown in FIG. 4 are results simulated assuming that the filler is uniformly contained in the mold resin.

FIG. 5A, FIG. 5B and FIG. 5C show examples of shapes of the chamfer of the first corner 1401. A width in the first direction Y axis when the first corner 1401 is projected on the Z-axis direction is set as a width w1, a width in the Z-axis direction along the first end surface 1412c when the first corner 1401 is projected to the Y-axis direction along the second surface 1412b of the conductive portion 141 is set as a width w2. In this case, either one of width w1 or width w2 may be greater than 15 μm and shorter than the thickness of the conductive portion 141. As described above, this allows for increasing the possibility of the presence of the filler in the chamfered portion.

When the first corner 1401 is chamfered, electric field concentration occurs at the corner. In particular, electric field concentration tends to occur at a corner closer to the signal processing IC 100. Accordingly, as shown in FIG. 5C, the width w1 is preferably longer than the width w2. This allows for further reducing electric field concentration in the vicinity of the first corner 1401.

As described above, the second portion 1412 is shifted with respect to the first portion 1411 due to half blanking processing of the conductive portion 141. In this manner, the second portion 1412 is shifted with respect to the first portion 1411 due to the half blanking processing, thereby the processing accuracy of the conductive portion 141 is increased. Accordingly, even if the conductive portion 141 is arranged near the signal processing IC 100, the possibility of the conductive portion 141 contacting the signal processing IC 100 during the manufacturing process due to manufacturing errors can be reduced.

On the other hand, for example, in the manufacturing process of the current sensor 10, the lead frame 140 may be pressed or the current sensor 10 may vibrate when the current sensor 10 is in a mounted state, which may cause stress to occur in the sealing portion 130. In this case, the stress concentrates at the corner of the lead frame 140. In particular, the stress concentrates in a portion close to the outer surface of the sealing portion 130, that is, in the vicinity of the third corner 1403. The third corner 1403 created by half blanking processing is sharp with respect to a case of using other processing methods that form steps, such as bending. Therefore, cracks are more likely to occur in the sealing portion 130 in the vicinity of the third corner 1403 than in other portions.

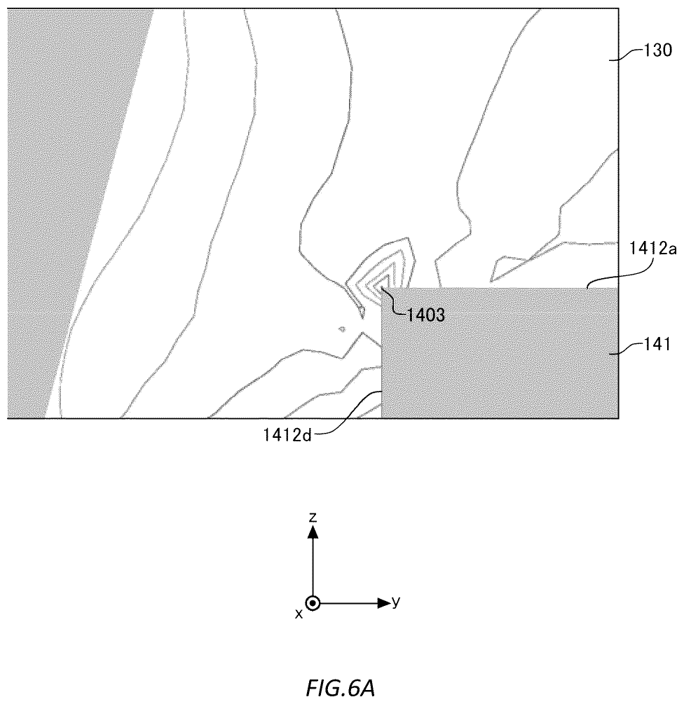

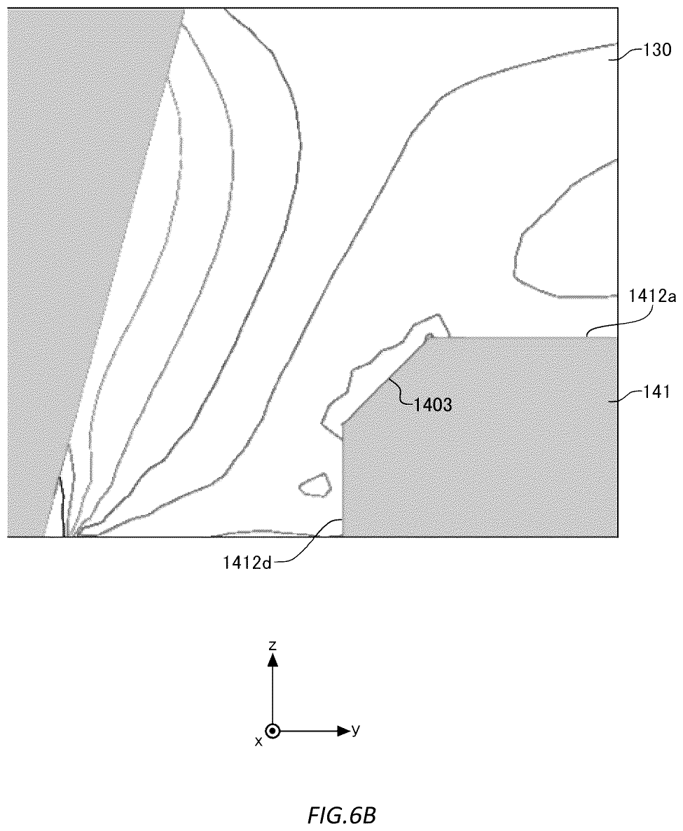

FIG. 6A and FIG. 6B show simulation results of the equivalent stress in the vicinity of the third corner 1403. FIG. 6A shows an example of simulation results of equivalent stress in a structure where a third corner 1403 is not chamfered. FIG. 6B shows an example of simulation results of equivalent stress in a structure where the third corner 1403 is chamfered. In a portion, the denser the stress contours are, the more concentrated the stress is in the portion. Therefore, as shown in FIG. 6A and FIG. 6B, it can be seen that chamfering the third corner 1403 can suppress stress concentration in the vicinity of the third corner 1403. That is, chamfering the third corner 1403 can suppress the occurrence of cracks.

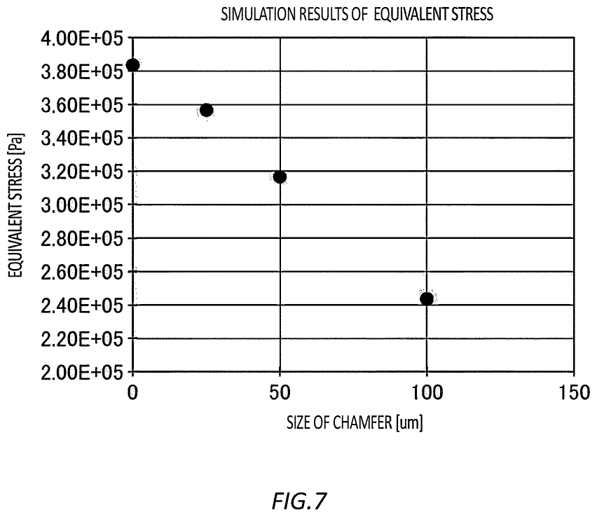

FIG. 7 shows an example of a relationship between a size of the chamfer and a magnitude of the equivalent stress. As shown in FIG. 7, the larger the chamfer, the lower the equivalent stress can be.

Herein, when a small crack occurs from a location where the equivalent stress is high, it is crucial to increase the toughness of the location in order to suppress the propagation of the crack. When delamination is caused at the interface between the filler inside the mold resin and the base material, the energy of delamination is high, so the inclusion of filler can increase the toughness of the base material against cracks in the base material, which is a fragile material such as epoxy. Therefore, it is preferable to have the interface present between the filler and the base material in the chamfer region where stress is concentrated.

As described above, the mold resin contains filler with a filler diameter (diameter) of 20 μm or greater, and the filler filling ratio is 60% or greater. When viewed on the line segment of the chamfered portion, the dimension drops to one dimension, so the filler diameter is approximately 15 μm. Considering that the filler filling ratio is 60% or greater when the surface is large than 15 μm×0.4/0.6=10 μm, there is a higher probability than 60% that an interface between the filler and the base material exists in the chamfered region. Accordingly, the length of the edges of the chamfer surface is preferably secured to be 10 μm or greater, preferably 15 μm or greater, which is the filler diameter in one dimension.

Therefore, either one of a width in a direction (Y-axis direction) along the first surface 1412a opposing the second surface 1412b of the conductive portion 141 when the third corner 1403 is projected to a direction (Z-axis direction) along the second end surface 1412d or a width in a direction (Z axis) along the second end surface 1412d when the third corner 1403 is projected to a direction (Y-axis direction) along the first surface 1412a of the conductive portion 141 is preferably greater than 15 μm and shorter than the thickness of the conductive portion 141. This allows suppressing the initial propagation of the cracks, and further improving the reliability of the current sensor 10.

As shown in FIG. 2, a shift amount S with respect to the first portion 1411 of the second portion 1412 is preferably 0.6 times or less of the thickness H of the conductive portion 141. This allows reducing the amount in which the second portion 1412 protrudes with respect to the first portion 1411, and relaxing the stress concentration of the mold resin.

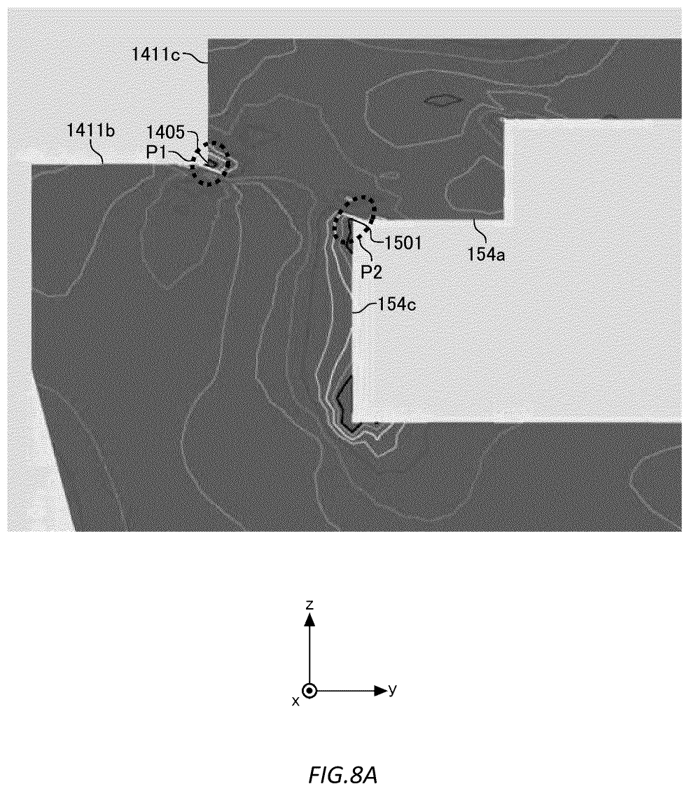

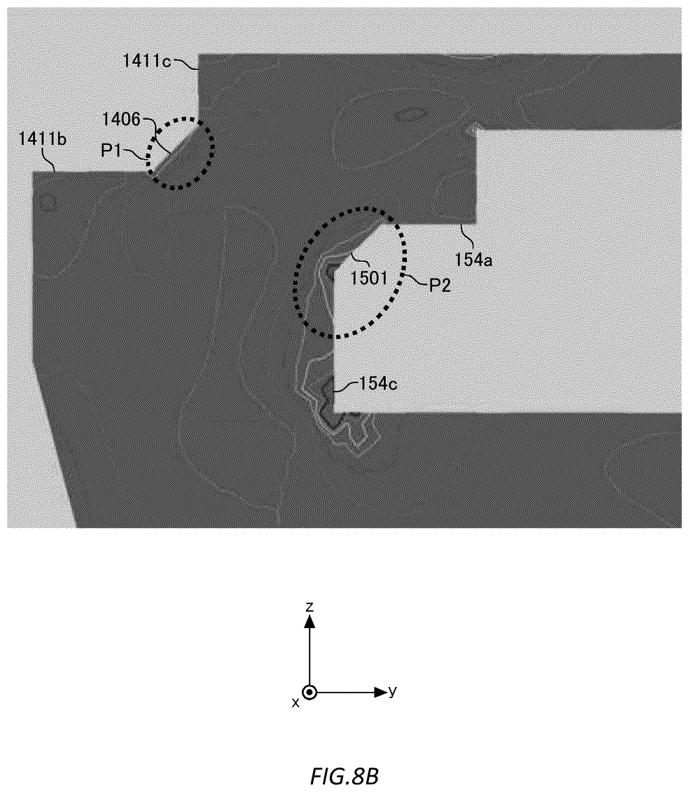

FIG. 8A and FIG. 8B show a distribution of the thermal stress when the temperature around the current sensor 10 is lowered and the mold resin shrinks. FIG. 8A shows an example of a simulation result of the thermal stress in a structure where the fifth corner 1405 and the seventh corner 1501 are not chamfered. FIG. 8B shows an example of a simulation result of the thermal stress in a structure where the fifth corner 1405 and the seventh corner 1501 are chamfered.

As shown in FIG. 8A and FIG. 8B, it can be seen that the thermal stress concentration in a region P1 in the vicinity of the fifth corner 1405 and a region P2 of the seventh corner 1501 when the fifth corner 1405 and the seventh corner 1501 are chamfered, is more relaxed than the thermal stress concentration in a region P1 in the vicinity of the fifth corner 1405 and a region P2 of the seventh corner 1501 when the fifth corner 1405 and the seventh corner 1501 are not chamfered.

Identical to the case of the third corner 1403, either one of a width in a direction (Y-axis direction) along the second surface 1411b of the first portion 1411 when the fifth corner 1405 is projected to a direction (Z-axis direction) along the third end surface 1411c or a width in a direction along the third end surface 1411c when the fifth corner 1405 is projected to a direction along the second surface 1411b of the first portion 1411 is preferably greater than 15 μm and shorter than the thickness of the conductive portion 141. In this manner, an interface between the filler and the base material tends to exist in the vicinity of the corner where thermal stress concentrates, the initial propagation of the cracks can be suppressed, and the reliability of the current sensor 10 can be further improved.

In the first embodiment, the current sensor 10 includes two magnetoelectric conversion elements 20a, 20b. However, it is sufficient if the current sensor 10 includes one or greater magnetoelectric conversion elements.

In the above descriptions, the example where each of the first corner 1401, the third corner 1403, the fifth corner 1405 and the seventh corner 1501 is chamfered in the current sensor 10 according to the first embodiment has been described. However, even if there is at least one chamfered corner of the first corner 1401, the third corner 1403, the fifth corner 1405 or the seventh corner 1501, an effect of relaxing electric field concentration or stress concentration can be achieved.

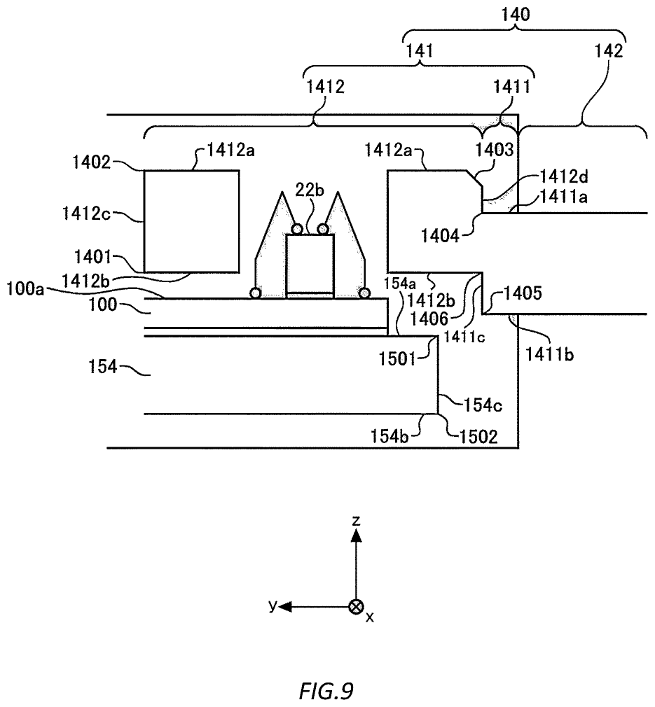

FIG. 9 shows an example of an enlarged drawing in the vicinity of the conductive portion 141 of the current sensor 10 according to the second embodiment. In a second embodiment, only the third corner 1403 of the conductive portion 141 is chamfered.

An outer surface area of the third corner 1403 is greater than an outer surface area of a fourth corner 1404 between the second end surface 1412d of the second portion 1412 and a first surface 1411a of the first portion 1411 on a side identical to the first surface 1412a of the second portion 1412. Either one of a width in a direction (Y-axis direction) along the first surface 1412a opposing the second surface 1412b of the conductive portion 141 when the third corner 1403 is projected to a direction (Z-axis direction) along the second end surface 1412d or a width in a direction (Z axis) along the second end surface 1412d when the third corner 1403 is projected to a direction (Y-axis direction) along the first surface 1412a of the conductive portion 141 may be greater than 15 μm and shorter than the thickness of the conductive portion 141. In the current sensor 10 according to the second embodiment, by chamfering the third corner 1403, the stress concentration in the vicinity of the third corner 1403 can be suppressed, and the occurrence of cracks can be suppressed.

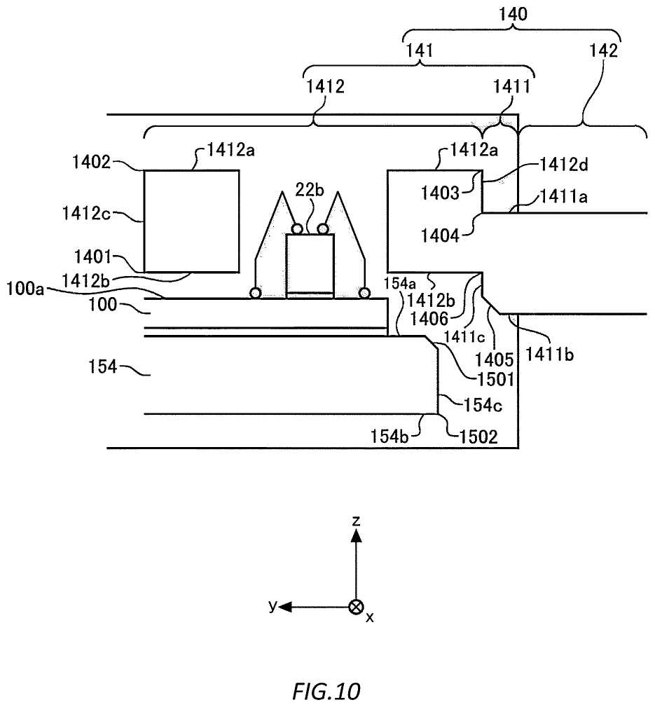

FIG. 10 shows an example of an enlarged drawing in the vicinity of the conductive portion 141 of the current sensor 10 according to the third embodiment. In the third embodiment, only the fifth corner 1405 of the conductive portion 141 and the seventh corner 1501 of the instruction unit 154 are chamfered. Only either one of the fifth corner 1405 of the conductive portion 141 or the seventh corner 1501 of the instruction unit 154 may be chamfered. An outer surface area of the fifth corner 1405 is greater than an outer surface area of a sixth corner 1406 between a third end surface 1411c of the first portion 1411 and the second surface 1412b of the second portion 1412. An outer surface area of the seventh corner 1501 is greater than an outer surface area of the eighth corner 1502.

Either one of a width in a direction (Y-axis direction) along the second surface 1411b of the first portion 1411 when the fifth corner 1405 is projected to a direction (Z-axis direction) along the third end surface 1411c or a width in a direction along the third end surface 1411c when the fifth corner 1405 is projected to a direction along the second surface 1411b of the first portion 1411 is preferably greater than 15 μm and shorter than the thickness of the conductive portion 141.

Either one of a width in a direction (Y-axis direction) along the surface 154a of the support portion 154 when the seventh corner 1501 is projected to a direction (Z-axis direction) along the fourth end surface 154c or a width in a direction along the fourth end surface 154c of the support portion 154 when the seventh corner 1501 is projected to a direction along the surface 154a of the support portion 154 is preferably greater than 15 μm and shorter than the thickness of the support portion 154.

In the current sensor 10 according to the third embodiment, an interface can easily exist between the filler and the base material in the vicinity of the corner where the thermal stress concentrates, the initial propagation of cracks can be suppressed, and the reliability of the current sensor 10 can be improved.

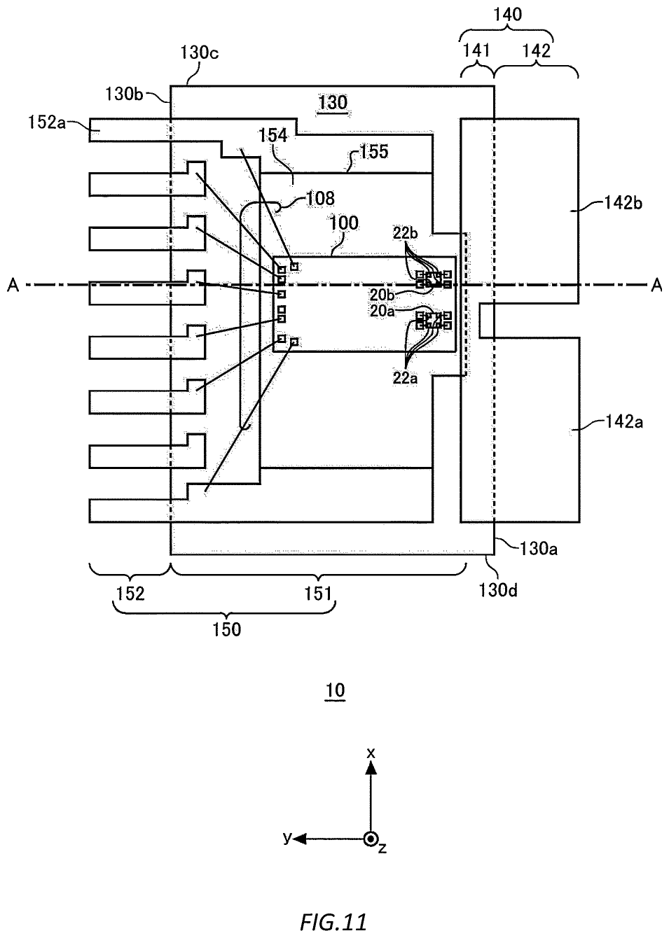

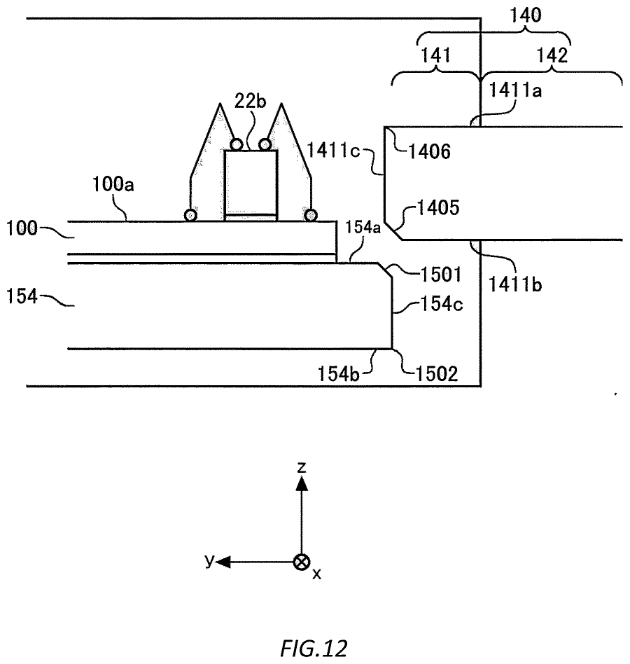

FIG. 11 is a schematic plan view of the current sensor 10 according to a fourth embodiment as viewed from the top surface side (in the Z-axis direction). FIG. 12 shows an example of an enlarged drawing in the vicinity of the conductive portion 141 in an A-A line sectional view of the current sensor shown in FIG. 11.

The current sensor 10 according to the fourth embodiment is different from the current sensor 10 according to the first embodiment to the third embodiment in a point that the conductive portion 141 does not have a slit portion for enclosing the magnetoelectric conversion elements 20a, 20b.

In the fourth embodiment, the conductive portion 141 has a fifth corner 1405 between a surface 1411b opposing the surface 1411a that is on a side identical to the surface 154a of the support portion 154 and the third end surface 1411c on the terminal portion 152 side, and a sixth corner 1406 between the surface 1411a of the conductive portion 141 and the third end surface 1411c. Then the outer surface area of the fifth corner 1405 is greater than the outer surface area of the sixth corner 1406. Either one of a width in a direction (Y-axis direction) along the surface 1411b of the conductive portion 141 when the fifth corner 1405 is projected to a direction (Z-axis direction) along the third end surface 1411c or a width in a direction along the third end surface 1411c when the fifth corner 1405 is projected to a direction along the surface 1411b of the conductive portion 141 is greater than 15 μm and shorter than the thickness of the conductive portion 141.

The support portion 154 has a seventh corner 1501 between the surface 154a that supports the signal processing IC 100 and a fourth end surface 154c on the terminal portion 142 side, and a eighth corner 1502 between the surface 154b opposing the surface 154a that supports the signal processing IC 100 and the fourth end surface 154c. An outer surface area of the seventh corner 1501 is greater than an outer surface area of the eighth corner.

In the current sensor 10 according to the fourth embodiment, an interface can easily exist between the filler and the base material in the vicinity of the corner where the thermal stress concentrates, the initial propagation of cracks can be suppressed, and the reliability of the current sensor 10 can be improved.

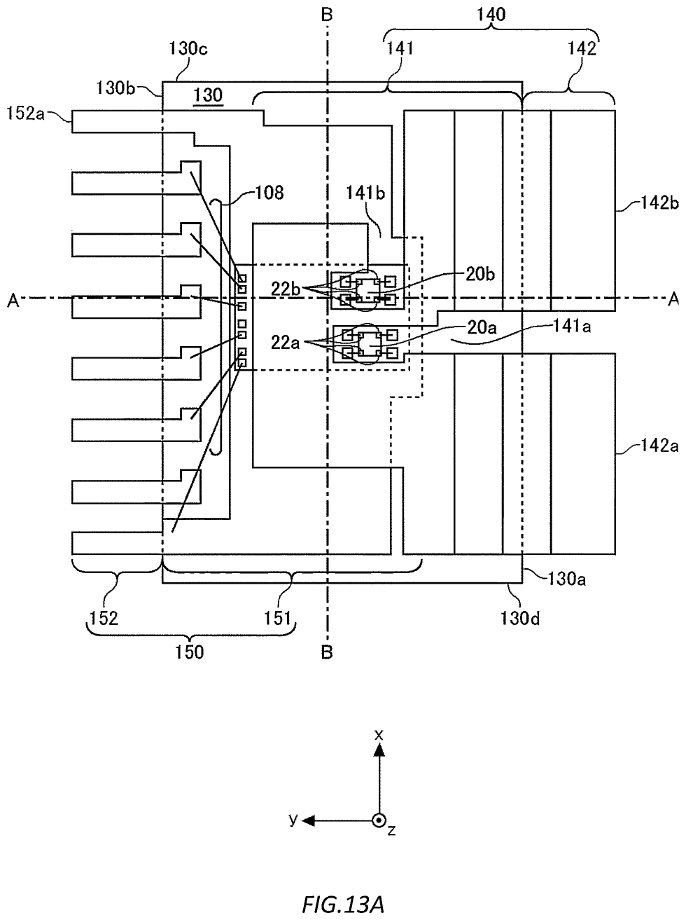

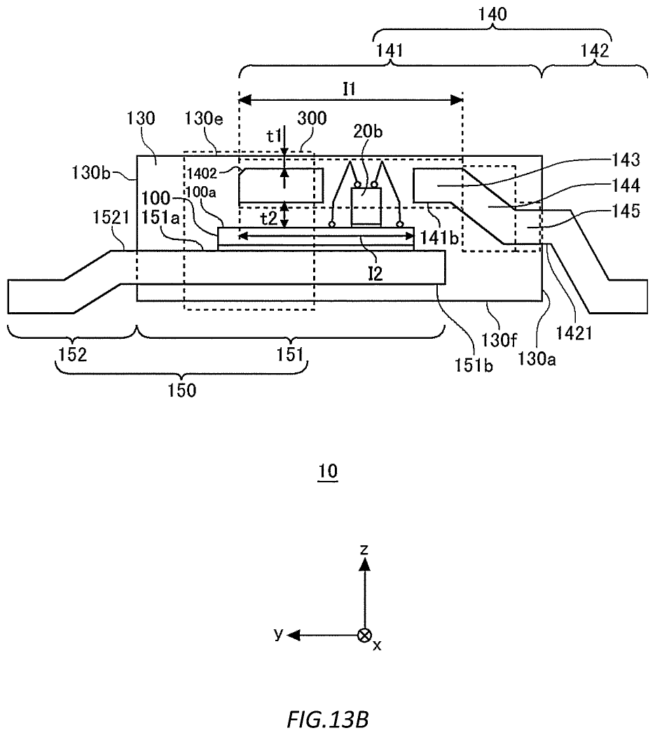

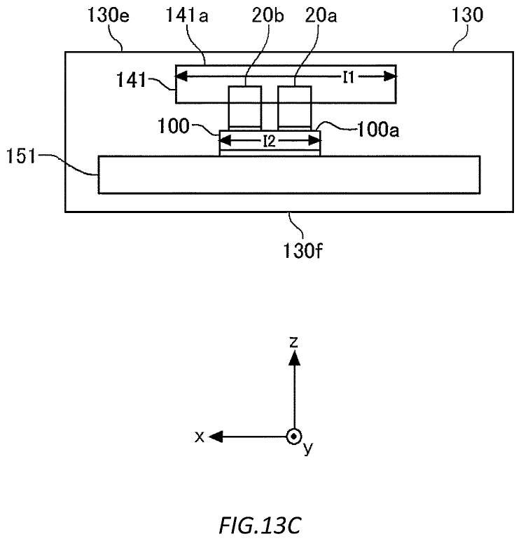

FIG. 13A, FIG. 13B and FIG. 13C shows an internal configuration of the semiconductor package that functions as a current sensor 10 according to the fifth embodiment. FIG. 13A is a schematic plan view of the current sensor 10 according to the fifth embodiment as viewed from the top surface side (in the Z-axis direction).

FIG. 13B is an A-A line sectional view of the current sensor 10 shown in FIG. 13A. FIG. 13C is a B-B line sectional view of the current sensor 10 shown in FIG. 13A. Hereafter, explanations may be omitted for the same signed configuration requirements described in the current sensor 10 shown in FIG. 1A and FIG. 1B.

The current sensor 10 comprises a signal processing IC 100, magnetoelectric conversion elements 20a, 20b, a lead frame 140 on the current conductor side, a lead frame 150 on the signal terminal side, and a sealing portion 130. This point is identical to the current sensor 10 according to the first embodiment in this point.

The lead frame 150 includes a support portion 151 and a terminal portion 152. The terminal portion 152 includes a plurality of terminals 152a. The support portion 151 is sealed inside the sealing portion 130, and supports the signal processing IC 100. Some terminals 152a of the plurality of terminals 152a are configured to be physically integrated with the support portion 151. At least a part of each of the plurality of terminals 152a is exposed to the outside of the sealing portion 130. The lead frame 150 is an example of a second lead frame. The lead frame 140 and the lead frame 150 may be composed of a conductor material principally made of copper. The support portion 151 may be composed in combination with an insulating member such as a metal plate separate from the lead frame 150, a plate composed of semiconductor or die-attach film.

The pair of terminals 142a, 142b and the plurality of terminals 152a are arranged to oppose each other via the signal processing IC 100 in a direction (Y-axis direction) that intersects with the thickness direction (Z-axis direction) of the signal processing IC 100. The direction intersecting the thickness direction may be a direction along a plane (XY plane) orthogonal to the thickness direction. The pair of terminals 142a, 142b are exposed from a side surface 130a of the sealing portion 130. The plurality of terminals 152a are exposed from a side surface 130b, which is a side opposite to the side surface 130a of the sealing portion 130.

As shown in FIG. 13B, the pair of terminals 142a, 142b and the plurality of terminals 152a may protrude from different heights from each other in the thickness direction of the sealing portion 130 of the side surface 130a and side surface 130b, which face each other, of the sealing portion 130, toward the outside. A surface 1521 on a side identical to the first surface 100a of the signal processing IC 100 of the plurality of terminals 152a and a surface 1421 on a side identical to the surface opposing the first surface 100a of the signal processing IC 100 of the pair of terminals 142a, 142b may be in positions at a height identical to each other in the thickness direction of the sealing portion 130 (Z-axis direction). Alternatively, the surface 1521 of the plurality of terminals 152a may be located downwardly in the thickness direction of the sealing portion 130 when compared to the surface 1421 of the pair of terminals 142a, 142b.

That is, a height in the thickness direction of the sealing portion 130 (Z-axis direction) of the surface 1521 on the side identical to the surface 100a of the signal processing IC 100 of the plurality of terminals 152a in a position intersecting the side surface 130a of the sealing portion 130 may be identical to a height in the thickness direction of the sealing portion 130 (Z-axis direction) of the surface 1421 on a side identical to the surface opposing the surface 100a of the signal processing IC 100 of the pair of terminals 142a, 142b in the position intersecting the side surface 130b of the sealing portion 130. Alternatively, the height in the thickness direction of the sealing portion 130 (Z-axis direction) of the surface 1521 of the plurality of terminals 152a in the position intersecting the side surface 130a of the sealing portion 130 may be located downwardly when compared to the height in the thickness direction of the sealing portion 130 (Z-axis direction) of the surface 1421 of the pair of terminals 142a, 142b in the position intersecting the side surface 130b of the sealing portion 130.

When the lead frame 140 and the lead frame 150 are arranged to stack in the thickness direction, in order to secure insulation between the lead frame 140 and the lead frame 150 or the signal processing IC 100, at least one of the lead frame 140 or the lead frame 150 is required to be provided with a step in the thickness direction.

The conductive portion 141 is bent and coupled to the terminal portion 142 so as to approach the second surface 130f on the second surface 151b side of the support portion 151 in the sealing portion 130 inside the sealing portion 130. The conductive portion 141 may be bent and coupled to the terminal portion 142 so that the surface in a portion coupled to the terminal portion 142 in the second surface 141b of the conductive portion 141 approaches more to the second surface 130f on the second surface 151b side of the support portion 151 in the sealing portion 130 by half or greater of the thickness of the conductive portion 141 when compared to the surface facing the first surface 100a that is the circuit surface of the signal processing IC 100 in the second surface 141b of the conductive portion 141. That is, the difference between the height of the portion coupled to the terminal portion 142 in the second surface 141b of the conductive portion 141 and the height of the surface facing the first surface 100a that is the circuit surface of the signal processing IC 100 in the second surface 141b of the conductive portion 141 may be half or greater of the thickness of the conductive portion 141. The conductive portion 141 may be bent and coupled to the terminal portion 142 so as to approach the second surface 130f on the second surface 151b side of the support portion 151 in the sealing portion 130 inside the sealing portion 130. The conductive portion 141 may be bent by a bending process.

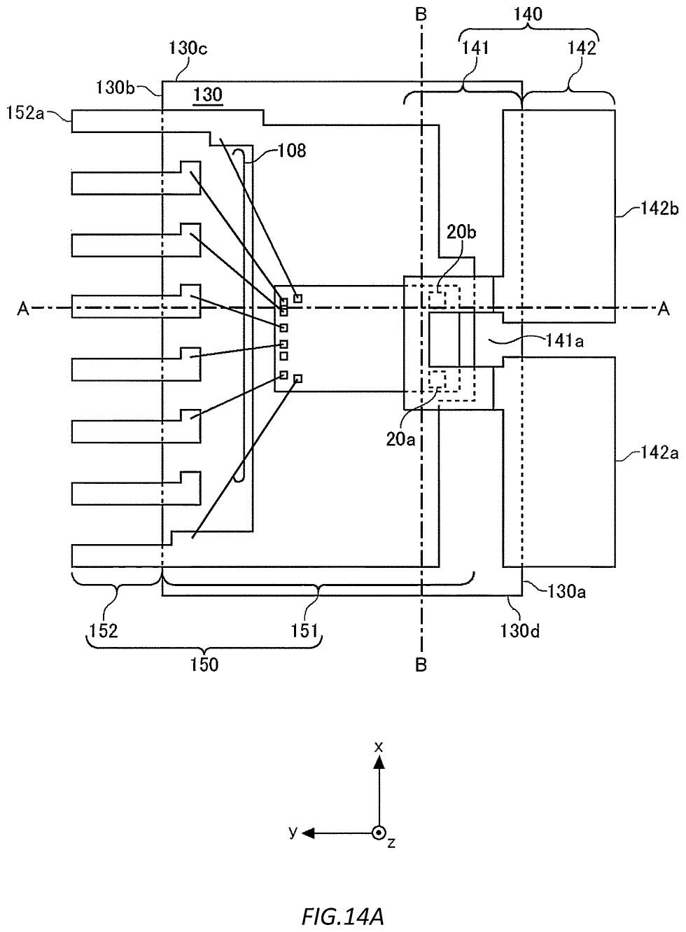

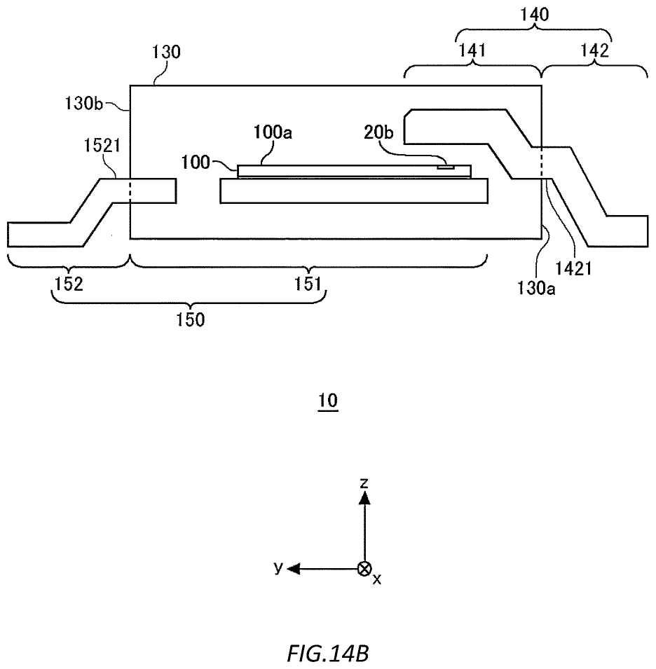

FIG. 14A and FIG. 14B show examples of the current sensor 10 in which the magnetoelectric conversion elements are arranged in positions for detecting a magnetic field in the X-axis direction. FIG. 14A shows an internal configuration of the semiconductor package that functions as a current sensor 10 according to a variant of the embodiment shown in FIG. 13A. FIG. 14A is a schematic plan view of a current sensor 10 according to a variant of the embodiment shown in FIG. 13A as viewed from the top surface side (in the Z-axis direction). FIG. 14B is an A-A line sectional view of the current sensor 10 shown in FIG. 14A. In the current sensor 10 according to the variant of the embodiment shown in FIG. 13A, the magnetoelectric conversion elements 20a, 20b are built in the chip composing the signal processing IC 100.

In a fifth embodiment, an example in which the current sensor 10 includes two magnetoelectric conversion elements 20a, 20b is described. However, the current sensor 10 may include at least one magnetoelectric conversion element.

The sealing portion 130 seals, with mold resin, the magnetoelectric conversion elements 20a, 20b, the conductive portion 141, the support portion 151, the signal processing IC 100, the wires 22 and the wire 108. The mold resin may be, for example, comprised of an epoxy-based thermally curable resin added with silica and formed into a semiconductor package by a transfer molding.

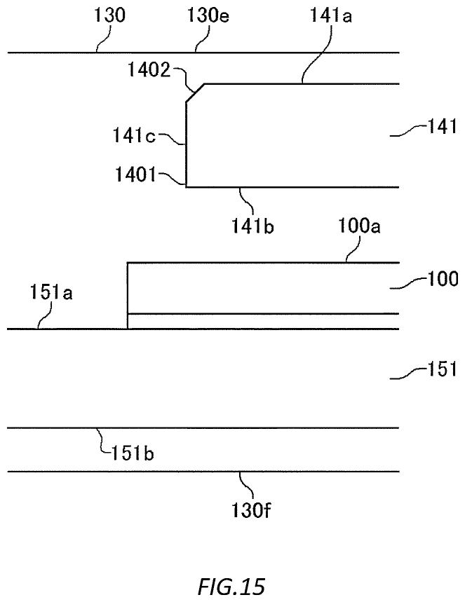

FIG. 15 shows an example of an enlarged drawing of an enclosed portion indicated by a sign 300 shown in FIG. 13B. The conductive portion 141 has a first corner 1401 between a first end surface 141c opposing a side coupled to the terminal portion 142 and a surface 141b facing the signal processing IC 100, and a second corner 1402 between the first end surface 141c and a first surface 141a opposing the second surface 141b facing the first surface 100a of the signal processing IC 100.

The second corner 1402 is a chamfered surface. An outer surface area of the second corner 1402 is greater than an outer surface area of the first corner 1401. The outer surface area of the first corner 1401 is an outer surface area defined from a boundary between the second surface 141b and the first corner 1401 to a boundary between the first end surface 141c and the first corner 1401. The outer surface area of the second corner 1402 is an outer surface area defined from a boundary between the first end surface 141c and the second corner 1402 to a boundary between the first surface 141a and the second corner 1402. The first corner 1401 may be approximately linear along the X-axis direction. The outer surface area of the first corner 1401 may be substantially zero.

In this manner, by chamfering the second corner 1402, the thermal stress concentration in the vicinity of the corner can be suppressed, occurrence of cracks of the sealing portion 130 can be suppressed, and the durability of the current sensor 10 can be improved.

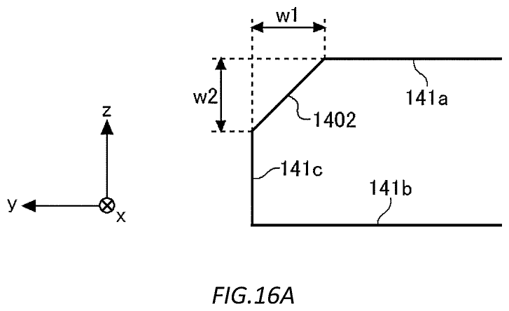

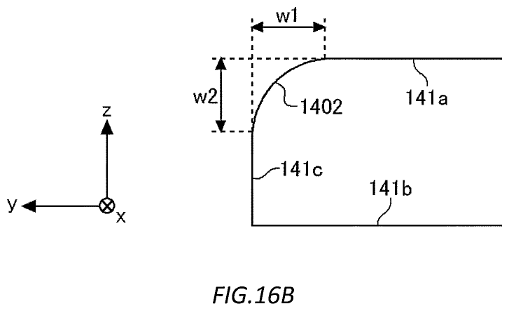

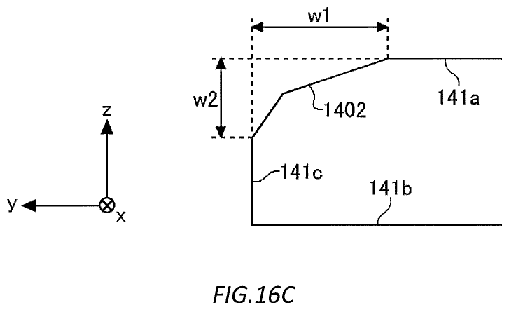

The shape of the chamfer of the second corner 1402 may be any shape, or may be composed of a plurality of surfaces that is obtained by combining a plurality of abbreviated planes. The shape of the chamfer may consist of one plane of an abbreviated plane as shown in FIG. 16A, one plane of an R surface (curved surface) as shown in FIG. 16B, or two planes combined with two abbreviated planes as shown in FIG. 16C. As FIG. 16B, when the second corner 1402 is an R surface, the outer surface area of the second corner 1402 is an area of the curved surface portion. The boundary between the first end surface 141c and the second corner 1402, and the boundary between the first surface 141a and the second corner 1402 are each a portion where the curved surface initiates.

In the following, the reasons why the thermal stress concentration in the vicinity of the corner can be suppressed by chamfering the second corner 1402 are to be described.

Herein, in a durability test of the current sensor 10, there is a test for testing a state of the current sensor 10 in the environment under a predetermined minimum temperature, for example, −65° C. In such an environment, the linear expansion coefficient of the lead frame 140 is greater than the linear expansion coefficient of the mold resin composing the sealing portion 130. Accordingly, the lead frame 140 exerts a greater force in the direction of shrinkage than the sealing portion 130. Therefore, the speed of shrinkage of the sealing portion 130 cannot keep up with the speed of shrinkage of the lead frame 140, and the sealing portion 130 is pulled by the lead frame 140. As a result, there is a possibility of the occurrence of cracks in the sealing portion 130.

In the case of a structure where the lead frame 140 and the lead frame 150 overlap in the thickness direction, the distance between the top surface (surface 130e) of the sealing portion 130 and the lead frame 140 becomes relatively short. That is, the mold resin between the top surface of the sealing portion 130 and the lead frame 140 becomes thinner. Alternatively, a distance between the bottom surface (surface 130f) of the sealing portion 130 and the lead frame 150 becomes relatively short. That is, the mold resin between the bottom surface of the sealing portion 130 and the lead frame 150 becomes thinner. Therefore, there is a possibility of occurrence of cracks between the top surface (surface 130e) of the sealing portion 130 and the lead frame 140, or between the bottom surface (surface 130f) of the sealing portion 130 and the lead frame 150.

In the case of a structure where the lead frame 140 and the lead frame 150 overlap in the thickness direction, inside the sealing portion, the step produced by bending process is preferably half or greater of the thickness of the lead frame 140 or the lead frame 150. This improves the precision of the bending process. It is not required to perform bending process to provide a step in the support portion 151 of the lead frame 150. However, the distance between the surface of the sealing portion 130 and the lead frame 140 or the lead frame 150 tends to become short.

In FIG. 13B and FIG. 13C, the conductive portion 141 has a step produced by bending process inside the sealing portion 130. That is, the conductive portion 141 has a flat portion 143, a stepped portion 144 and a flat portion 145 that are grouped physically. Inside the conductive portion 141, the flat portion 143 is a portion closest to the top surface of sealing. Herein, as shown in FIG. 13B and FIG. 13C, when the distance between the first surface 130e on the first surface 141a side of the conductive portion 141 and the first surface 141a of the conductive portion 141 in the sealing portion 130 is set as t1, the width in the X-axis direction intersecting the Y-axis direction along the first surface 141a of the conductive portion 141 of the flat portion 143 is set as l1, the distance between the second surface 141b of the conductive portion 141 and the first surface 100a of the signal processing IC 100 is set as t2, and in the width in the X-axis direction along the first surface 100a of the signal processing IC 100, the portion facing the second surface 141b of the flat portion 143 is set as l2, l1/t1>l2/t2 is satisfied. Alternatively, in this case, the aspect ratio of the mold resin with a thickness of t1 has a aspect ratio greater than that of the mold resin with a thickness of t2, and in the sealing portion 130, in the interface between the lead frame 140 that has undergone the bending process and the sealing portion 130, the stress of the first corner 1401 closest to the surface of the sealing portion 130 becomes maximum.

In the flat portion 143, when the length in the Y-axis direction along the first surface 141a of the conductive portion 141 is set as l1, in the width in the Y-axis direction along the first surface 100a of the signal processing IC 100, the portion facing the second surface 141b of the flat portion 143 is set as l2, and l1/t1>l2/t2 is satisfied, inside the sealing portion 130, in the interface between the lead frame 140 that has undergone the bending process and the sealing portion 130, the stress of the first corner 1401 closest to the surface of the sealing portion 130 becomes maximum.

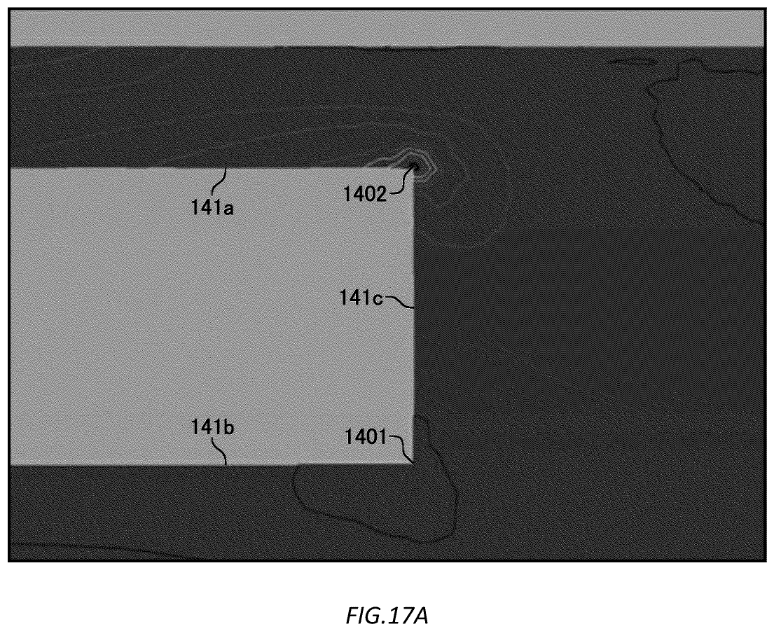

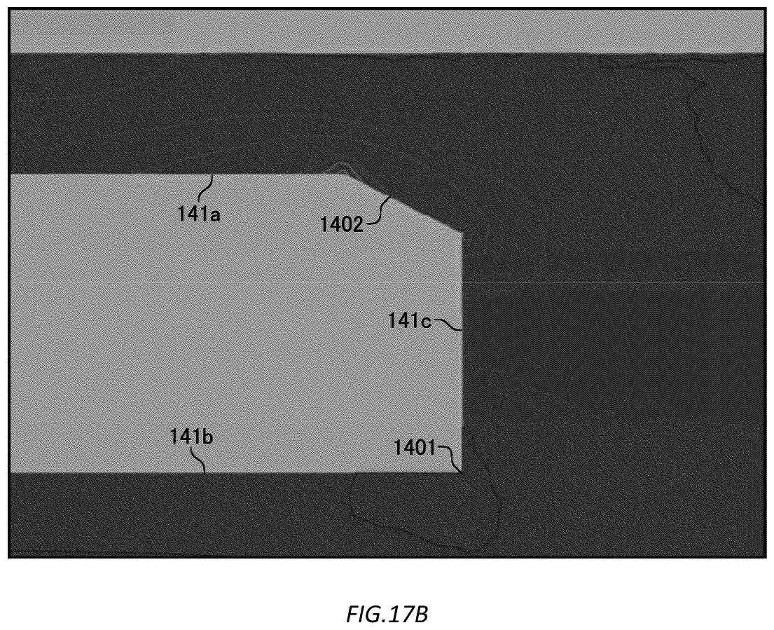

FIG. 17A shows an example of simulation results of thermal stress when the current sensor 10 is placed in an environment with a minimum temperature of −65° C., which is required for a durability test in a structure where the second corner 1402 is not chamfered. FIG. 17B shows an example of simulation results of thermal stress when the current sensor 10 is placed in an environment with a minimum temperature of −65° C., which is required for a durability test in a structure where the second corner 1402 is chamfered. FIG. 17A and FIG. 17b show contour plots of the thermal stress. When comparing FIG. 17A and FIG. 17B, in the vicinity of the second corner 1402, the contour of the thermal stress shown in FIG. 17A can be seen to be denser than the contour of the thermal stress shown in FIG. 17B. That is, it can be seen that the thermal stress is more likely to be concentrated in the vicinity of the second corner 1402 if not chamfered.

In a case of a structure where the lead frame 140 on the current conductor side and the lead frame 150 on the signal terminal side are stacked in the thickness direction, the portion where the thermal stress tends to concentrate most is the second corner 1402 of the leading portion of the sealing portion 130 in the conductive portion 141 of the lead frame 140 on the current conductor side. Therefore, chamfering the second corner 1402 can suppress thermal stress concentration and improve the durability of the current sensor 10.

The mold resin composing the sealing portion 130 contains a large amount of filler. The mold resin contains filler with a filler diameter (diameter) of 20 μm or greater, and the filler filling ratio is 60% or greater. The mode diameter of the filler contained in the mold resin is approximately 20 μm. And if there exists a sphere with a diameter of approximately 20 μm in three dimensions, the filler diameter is approximately 15 μm (20 μm×(√3/2)²), since the dimension drops to one dimension when viewed on the line segment of the chamfered portion.

Herein, when a small crack occurs from a location where the equivalent stress is high, it is crucial to increase the toughness of the location in order to suppress the propagation of the crack. When delamination is caused at the interface between the filler inside the mold resin and the base material, the energy of delamination is high, so the inclusion of filler can increase the toughness of the base material against cracks in the base material, which is a fragile material such as epoxy. Therefore, it is preferable to have the interface present between the filler and the base material in the chamfer region where stress is concentrated. That is, when the filler exists on the surface of the conductive portion 141, the filler is difficult to delaminate from the surface of the conductive portion 141, and cracks hardly occur in the sealing portion 130. Therefore, if the width of the chamfered surface is equal to or greater than the filler diameter, the possibility of filler being present in the chamfered portion is very high, making it difficult for cracks to occur in the sealing portion 130.

As described above, the mold resin composing the sealing portion 130 contains filler with a filler diameter (diameter) of 20 μm or greater, and the filler filling ratio is 60% or greater. When viewed on the line segment of the chamfered portion, the dimension drops to one dimension, so the filler diameter is approximately 15 μm. Considering that the filler filling ratio is 60% or greater when the surface is larger than 15 μm×0.4/0.6=10 μm, there is a higher probability than 60% that an interface between the filler and the base material exists in the chamfered region. Accordingly, the length of the edges of the chamfer surface is preferably secured to be 10 μm or greater, preferably 15 μm or greater, which is the filler diameter in one dimension.

FIG. 16A, FIG. 16B and FIG. 16C show examples of shapes of the chamfer of the second corner 1402. A width in the first direction Y axis, when the second corner 1402 is projected on the Z-axis direction, is set as a width w1, a width in the Z-axis direction along the first end surface 1412c when the second corner 1402 is projected to the Y-axis direction along the first surface 141a of the conductive portion 141 is set as a width w2. In this case, either one of width w1 or width w2 may be greater than 15 μm and shorter than the thickness of the conductive portion 141. As described above, this allows for increasing the possibility of the presence of the filler in the chamfered portion. This allows suppressing the initial propagation of the cracks, and further improving the reliability of the current sensor 10.

In the current sensor 10 according to the fifth embodiment, an interface can easily exist between the filler and the base material in the vicinity of the corner where the thermal stress concentrates, the initial propagation of cracks can be suppressed, and the reliability of the current sensor 10 can be improved.

In the above-described embodiment, the form in which the lead frame 140 is bent is described. However, the lead frame 150 may be bent instead of the lead frame 140.

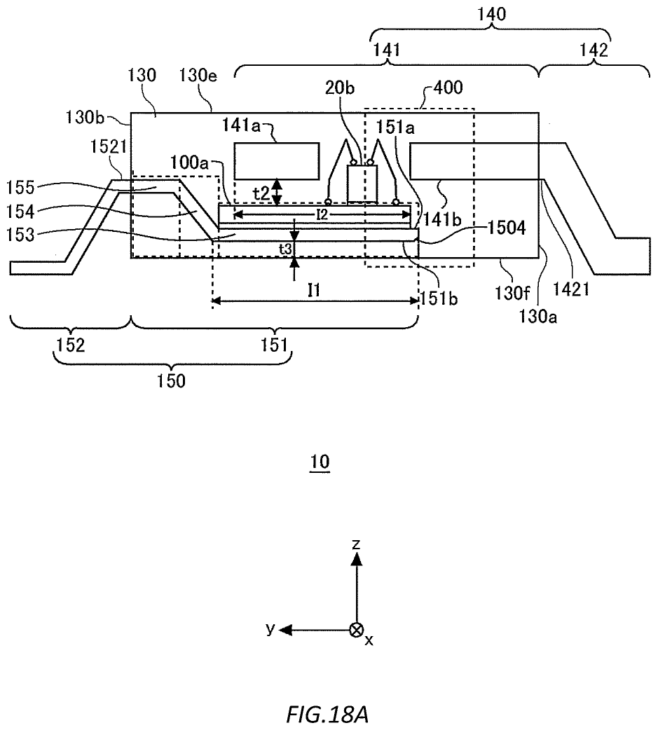

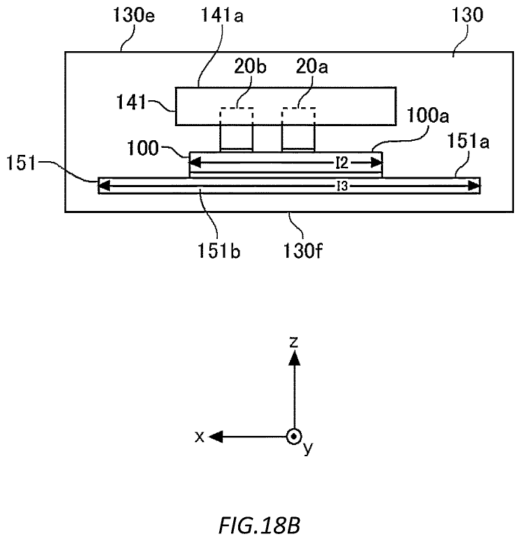

FIG. 18A is a cross-sectional view of the current sensor 10 as viewed from the X-axis direction. FIG. 18B is a cross-sectional view of the current sensor 10 as viewed from the Y-axis direction.

The current sensor 10 according to a sixth embodiment has the lead frame 150 bent instead of the lead frame 140, and is different from the current sensor 10 according to the fifth embodiment in a point that the fourth corner 1504 of the support portion 151 is chamfered instead of the second corner 1401 of the conductive portion 141.

The support portion 151 is bent and coupled to the terminal portion 152 so as to approach the first surface 130e on the first surface 141a side of the conductive portion 141 in the sealing portion 130. The support portion 151 may be bent and coupled to the terminal portion 152 so that the surface of the portion coupled to the terminal portion 152 in the first surface 151a of the support portion 151 approaches more to the first surface 130e on the first surface 141a side of the conductive portion 141 in the sealing portion 130 by half or greater of the thickness of the support portion 151 when compared to the surface supporting the signal processing IC 100 in the first surface 151a of the support portion 151.

The pair of terminals 142a, 142b protrude from the side surface 130a to the negative side in the Y-axis direction, and are further bent to the negative side in the Z-axis direction. The plurality of terminals 152a protrude from the side surface 130b to the positive side in the Y-axis direction, and are further bent to the negative side in the Z-axis direction.

When the current to-be-measured flows through the lead frame 140, since heat is generated in response to electrical resistance, it is preferable to lower the electrical resistance by increasing the plate thickness or by other means. On the other hand, when performing bending process on the lead frame, a step in any size can be formed regardless of the plate thickness. Therefore, even if a thin lead frame is used for the lead frame 150 to reduce the amount of material used, the desired step can still be formed. As a result, the lead frame 150 may become thinner than the lead frame 140.

As described above, in the case of a structure in which the lead frame 140 and the lead frame 150 overlap in the thickness direction, the distance between the bottom surface (surface 130f) of the sealing portion 130 and the lead frame 150 becomes relatively short. That is, the mold resin between the bottom surface of the sealing portion 130 and the lead frame 150 becomes thinner. Therefore, there is a possibility of occurrence of cracks between the bottom surface of the sealing portion 130 and the lead frame 150.

In the case of a structure where the lead frame 140 and the lead frame 150 overlap in the thickness direction, the step produced by bending process is preferably half or greater of the thickness of the lead frame 140 or the lead frame 150. This improves the precision of the bending process. It is not required to perform bending process to provide a step in the conductive portion 141 of the lead frame 140. However, the distance between the surface of the sealing portion 130 and the lead frame 150 tends to become shorter.

In FIG. 6A and FIG. 6B, the support portion 151 has a step produced by bending process inside the sealing portion 130. That is, the support portion 151 has a flat portion 153, a stepped portion 154 and a flat portion 155 grouped physically. Inside the support portion 151, the flat portion 153 is a portion closest to the bottom surface of sealing. Herein, as shown in FIG. 18A and FIG. 18B, when the distance between the second surface 130f on the second surface 151b side of the support portion 151 in the sealing portion 130 and the second surface 151b of the support portion 151 is set as t3, the width in the X-axis direction along the second surface 151b of the support portion 151 is set as l3, the distance between the second surface 141b of the conductive portion 141 and the first surface 100a of the signal processing IC 100 is set as t2, and in the width in the X-axis direction along the first surface 100a of the signal processing IC 100, the width of the portion facing the second surface 141b of the conductive portion 141 is set as l2, l3/t3>l2/t2 is satisfied. In this case, the aspect ratio of the mold resin with a thickness of t3 has a aspect ratio greater than that of the mold resin with a thickness of t2, and in the sealing portion 130, in the interface between the lead frame 150 that has undergone the bending process and the sealing portion 130, the stress of the fourth corner 1504 closest to the surface of the sealing portion 130 becomes maximum.

In the flat portion 153, when the length in the Y-axis direction along the second surface 151b of the support portion 151 is set as l1, in the width in the Y-axis direction along the first surface 100a of the signal processing IC 100, the portion facing the second surface 141b of the conductive portion 141 is set as l2, and l1/t1>l2/t2 is satisfied, inside the sealing portion 130, in the interface between the lead frame 140 that has undergone the bending process and the sealing portion 130, the stress of the first corner 1401 closest to the surface of the sealing portion 130 becomes maximum.

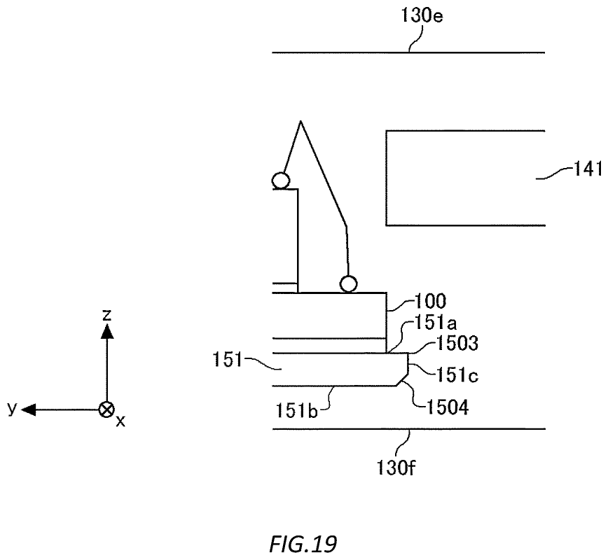

FIG. 19 shows an example of an enlarged drawing of the enclosed portion indicated by the sign 400 shown in FIG. 18A. The support portion 151 has a third corner 1503 between the second end surface 151c opposing a side coupled to the terminal portion 152 and the first surface 151a of the support portion 151 that supports the signal processing IC 100, and a fourth corner 1504 between the second end surface 151c and the second surface 151b opposing the first surface 151a of the support portion 151.

The outer surface area of the third corner 1503 is an outer surface area defined from a boundary between the third surface 151a and the third corner 1503, to a boundary between the second end surface 151c and the third corner 1503. The outer surface area of the fourth corner 1504 is an outer surface area defined from a boundary between the second end surface 151c and the fourth corner 1504 to a boundary between the second surface 151b and the fourth corner 1504. The outer surface area of the third corner 1503 may be substantially zero.

As described above, the stress of the fourth corner 1504 closest to the surface of the sealing portion 130 becomes maximum. Therefore, the fourth corner 1504 is chamfered. That is, the outer surface area of the fourth corner 1504 is greater than the outer surface area of the third corner 1503. In this manner, by chamfering the fourth corner 1504, the thermal stress concentration in the vicinity of the corner can be suppressed, occurrence of cracks of the sealing portion 130 can be suppressed, and the durability of the current sensor 10 can be improved.

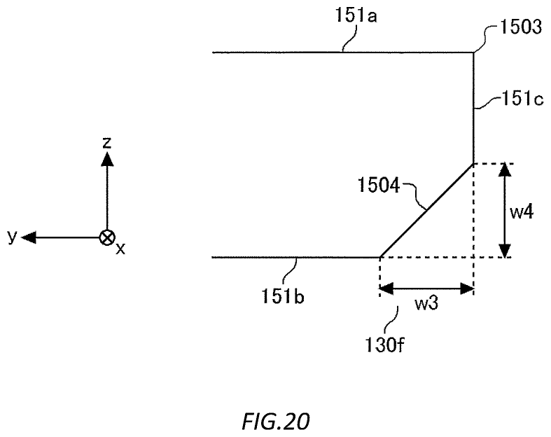

FIG. 20 shows an example of a shape of the chamfer of the fourth corner 1504. The width in the direction along the second surface 151b of the support portion 151 when the fourth corner 1504 is projected to the Z-axis direction along the second end surface 151c is set as a width w3, and the width in the Z-axis direction along the second end surface 151c when the fourth corner 1504 is projected to the Y-axis direction along the second surface 151b of the support portion 151 is set as a width w4. In this case, either one of the width w3 or the width w4 is greater than 15 μm and shorter than the thickness of the support portion 151. As described above, this allows for increasing the possibility of the presence of the filler in the chamfered portion. This allows suppressing the initial propagation of the cracks, and further improving the reliability of the current sensor 10.

While the present invention has been described with the embodiments, the technical scope of the present invention is not limited to the above-described embodiments. It is apparent to persons skilled in the art that various alterations or improvements can be added to the above-described embodiments. It is also apparent from the description of the claims that the form to which such alterations or improvements are made can be included in the technical scope of the present invention.

It should be noted that the operations, procedures, steps, stages, and the like of each process performed by an apparatus, system, program, and method shown in the claims, the specification, or the drawings can be realized in any order as long as the order is not indicated by “prior to,” “before,” or the like and as long as the output from a previous process is not used in a later process. Even if the operation flow is described by using phrases such as “first” or “next” for the sake of convenience in the claims, specification, and drawings, it does not necessarily mean that the process must be performed in this order.

### OTHER POSSIBLE ITEMS

### Item 1

A current sensor, comprising:
at least one magnetoelectric conversion element;
a first lead frame having a first terminal portion and a conductive portion coupled to the first terminal portion, wherein a measurement current measured by the at least one magnetoelectric conversion element flows through the first terminal portion and the conductive portion;
a signal processing IC that processes a signal output from the at least one magnetoelectric conversion element, arranged on a second surface side opposing a first surface of the conductive portion, having a circuit surface facing the second surface, with the at least one magnetoelectric conversion element arranged thereon; and
a sealing portion that seals the at least one magnetoelectric conversion element, the conductive portion and the signal processing IC,
wherein the conductive portion has a first corner between a first end surface opposing a side coupled to the first terminal portion and a second surface facing the signal processing IC, and a second corner between the first end surface and a first surface opposing the second surface facing the signal processing IC; and
wherein an outer surface area of the first corner is greater than an outer surface area of the second corner.

### Item 2

The current sensor according to item 1, wherein the first corner is a chamfered surface.

### Item 3

The current sensor according to item 1, wherein either one of a width in a direction along the second surface of the conductive portion when the first corner is projected in a direction along the first end surface or a width in a direction along the first end surface when the first corner is projected in a direction along the second surface of the conductive portion is greater than 15 μm and shorter than a thickness of the conductive portion.

### Item 4

The current sensor according to item 1, wherein a width in a direction along the second surface of the conductive portion when the first corner is projected in a direction along the first end surface is longer than a width in a direction along the first end surface when the first corner is projected in a direction along the second surface of the conductive portion.

### Item 5

The current sensor according to claim 1, wherein:
the conductive portion has:
   a first portion coupled to the first terminal portion; and
   a second portion arranged facing the circuit surface of the signal processing IC, being shifted with respect to the first portion and coupled to the first portion in a direction away from the circuit surface of the signal processing IC in a thickness direction;
the second portion has a third corner between a second end surface on a side coupled to the first portion and a first surface opposing a second surface facing the circuit surface of the signal processing IC; and
an outer surface area of the third corner is greater than an outer surface area of a fourth corner between the second end surface of the second portion and a first surface of the first portion, which is on a side identical to the first surface of the second portion.

### Item 6

The current sensor according to item 5, wherein the third corner is a chamfered surface.

### Item 7

The current sensor according to item 5, wherein either one of a width in a direction along a first surface opposing the second surface of the conductive portion when the third corner is projected in a direction along the second end surface or a width in a direction along the second end surface when the third corner is projected in a direction along the first surface of the conductive portion is greater than 15 μm and shorter than a thickness of the conductive portion.

### Item 8

The current sensor according to item 5, wherein a shift amount of the second portion with respect to the first portion is 0.6 times or less of a thickness of the conductive portion.

### Item 9

The current sensor according to item 5, wherein the second end surface of the second portion has a sheared surface.

### Item 10

The current sensor according to item 5, further comprising
a second lead frame, electrically insulated from the first lead frame, arranged to face the first terminal portion with the signal processing IC sandwiched therebetween in a planar view, having a second terminal portion electrically coupled to the signal processing IC and a support portion that supports, on a first surface, a surface opposing the circuit surface on a side of the conductive portion of the signal processing IC,
wherein the first portion has a fifth corner between a third end surface on a side coupled to the second portion and a second surface on a side identical to the second surface of the second portion; and
wherein an outer surface area of the fifth corner is greater than an outer surface area of a sixth corner between the third end surface of the first portion and the second surface of the second portion.

### Item 11

The current sensor according to item 10, wherein the fifth corner is a chamfered surface.

### Item 12

The current sensor according to item 10, wherein either one of a width in a direction along the second surface of the first portion when the fifth corner is projected in a direction along the third end surface or a width in a direction along the third end surface when the fifth corner is projected in a direction along the second surface of the first portion is greater than 15 μm and is shorter than a thickness of the conductive portion.

### Item 13

The current sensor according to item 10, wherein:
the support portion has a seventh corner between the first surface that supports the signal processing IC and a fourth end surface on a side of the first terminal portion, and an eighth corner between a second surface opposing the first surface that supports the signal processing IC and the fourth end surface; and
an outer surface area of the seventh corner is greater than an outer surface area of the eighth corner.

### Item 14

The current sensor according to any one of items 3, 7, 11, wherein the sealing portion is composed of mold resin, and the mold resin contains filler with a diameter of 20 um or greater, and a filler filling ratio is 60% or greater.

### Item 15

The current sensor according to item 1, wherein the at least one magnetoelectric conversion element protrudes from the circuit surface up to a position overlapping the conductive portion as viewed from a direction intersecting a thickness direction of the at least one magnetoelectric conversion element.

### Item 16

The current sensor according to item 1, wherein the at least one magnetoelectric conversion element is composed of another chip different from a chip composing the signal processing IC.

### Item 17

The current sensor according to item 1, wherein the at least one magnetoelectric conversion element is built in a chip composing the signal processing IC.

### Item 18

The current sensor according to item 1, wherein:
the conductive portion has at least one slit portion; and
the at least one magnetoelectric conversion element is at least partially enclosed by the conductive portion by being respectively arranged inside the at least one slit portion in a planar view.

### Item 19

The current sensor according to item 18, wherein the at least one magnetoelectric conversion element is respectively fixed on the circuit surface by die bonding inside the at least one slit portion, and is electrically coupled to the signal processing IC by wire bonding in a planar view.

### Item 20

The current sensor according to item 19, wherein a magnetosensitive surface of the at least one magnetoelectric conversion element is arranged in a position overlapping a side surface with the at least one slit of the conductive portion provided thereon as viewed from a direction intersecting a thickness direction of the at least one magnetoelectric conversion element.

### Item 21

The current sensor according to item 1, wherein the at least one magnetoelectric conversion element is a hall element that detects a longitudinal magnetic field in a thickness direction of the conductive portion.

### Item 22

The current sensor according to item 1, wherein the at least one magnetoelectric conversion element is a magneto-resistance element that detects a transverse magnetic field in a direction along the second surface of the conductive portion.

### Item 23

A current sensor, comprising:
at least one magnetoelectric conversion element;
a first lead frame having a first terminal portion and a conductive portion coupled to the first terminal portion, wherein a measurement current measured by the at least one magnetoelectric conversion element flows through the first terminal portion and the conductive portion;
a signal processing IC that processes a signal output from the at least one magnetoelectric conversion element, arranged on a second surface side opposing a first surface of the conductive portion, having a circuit surface facing the second surface, with the at least one magnetoelectric conversion element arranged thereon; and
a sealing portion that seals the at least one magnetoelectric conversion element, the conductive portion and the signal processing IC,
wherein the conductive portion has:
   a first portion coupled to the first terminal portion; and
   a second portion arranged facing the circuit surface of the signal processing IC, being shifted with respect to the first portion and coupled to the first portion in a direction away from the circuit surface of the signal processing IC in a thickness direction;
wherein the second portion has a third corner between a second end surface on a side coupled to the first portion and a first surface opposing a second surface facing the circuit surface of the signal processing IC; and
an outer surface area of the third corner is greater than an outer surface area of a fourth corner between the second end surface of the second portion and a first surface of the first portion, which is on a side identical to the first surface of the second portion.

### Item 24

The current sensor according to item 23, wherein the second end surface of the second portion has a sheared surface.

### Item 25

A current sensor, comprising:
at least one magnetoelectric conversion element;
a first lead frame having a first terminal portion and a conductive portion coupled to the first terminal portion, wherein a measurement current measured by the at least one magnetoelectric conversion element flows through the first terminal portion and the conductive portion;
a signal processing IC that processes a signal output from the at least one magnetoelectric conversion element, having a circuit surface with the at least one magnetoelectric conversion element arranged thereon;
a second lead frame, electrically insulated from the first lead frame, arranged to face the first terminal portion with the signal processing IC sandwiched therebetween in a planar view, having a second terminal portion electrically coupled to the signal processing IC and a support portion that supports the signal processing IC on a first surface; and
a sealing portion that seals the at least one magnetoelectric conversion element, the conductive portion, the signal processing IC and the support portion,
wherein the conductive portion includes a first sheared surface that is a step or an end surface with a sheared surface, on a side closer to the first terminal portion than the signal processing IC in a planar view and facing toward a side of the second terminal portion, with an outer surface area of a fifth corner closer to a second surface opposing the first surface of the support portion is greater than an outer surface area of a sixth corner further from the second surface at a corner of the first sheared surface.

### Item 26

A current sensor, comprising:
at least one magnetoelectric conversion element;
a first lead frame having a first terminal portion and a conductive portion coupled to the first terminal portion, wherein a measurement current measured by the at least one magnetoelectric conversion element flows through the first terminal portion and the conductive portion;
a signal processing IC that processes a signal output from the at least one magnetoelectric conversion element, having a circuit surface with the at least one magnetoelectric conversion element arranged thereon;
a second lead frame, electrically insulated from the first lead frame, arranged to face the first terminal portion with the signal processing IC sandwiched therebetween in a planar view, having a second terminal portion electrically coupled to the signal processing IC and a support portion that supports the signal processing IC on a first surface; and
a sealing portion that seals the at least one magnetoelectric conversion element, the conductive portion, the signal processing IC and the support portion,

Wherein the support portion has a seventh corner between the first surface that supports the signal processing IC and a second end surface on a side of the first terminal portion, and an eighth corner between a second surface opposing the first surface that supports the signal processing IC and the second end surface; and
an outer surface area of the seventh corner is greater than an outer surface area of the eighth corner.

### OTHER POSSIBLE ITEMS

### Item 1

A current sensor, comprising:
at least one magnetoelectric conversion unit;
a first lead frame having a first terminal portion and a conductive portion coupled to the first terminal portion, wherein a measurement current measured by the at least one magnetoelectric conversion unit flows through the first terminal portion and the conductive portion;
a signal processing unit that processes a signal output from the at least one magnetoelectric conversion unit, arranged on a second surface side opposing a first surface of the conductive portion, having a circuit surface facing the second surface of the conductive portion, with the at least one magnetoelectric conversion unit arranged on the circuit surface;
a second lead frame having a support portion that supports, on a first surface, a support surface opposing the circuit surface on a side of the conductive portion of the signal processing unit, and a second terminal portion coupled to the support portion, which outputs a signal from the signal processing unit; and
a sealing portion that seals the at least one magnetoelectric conversion unit, the conductive portion, the signal processing unit and the support portion,
wherein the conductive portion has a first corner between a first end surface opposing a side coupled to the first terminal portion and a second surface facing the signal processing unit, and a second corner between the first end surface and the first surface of the conductive portion;
wherein the support portion has a third corner between a second end surface opposing a side coupled to the second terminal portion and the first surface of the support portion that supports the signal processing unit, and a fourth corner between the second end surface and a second surface opposing the first surface of the support portion; and
wherein an outer surface area of the second corner is greater than an outer surface area of the first corner, or an outer surface area of the fourth corner is greater than an outer surface area of the third corner.

### Item 2

The current sensor according to item 1, wherein an outer surface area of the second corner is greater than an outer surface area of the first corner, and the conductive portion is bent to be coupled to the first terminal portion so as to approach a second surface of the second surface side of the support portion in the sealing portion.

### Item 3

The current sensor according to item 1, wherein an outer surface area of the second corner is greater than an outer surface area of the first corner, and the conductive portion is bent to be coupled to the first terminal portion so that a surface of a portion coupled to the first terminal portion on the second surface of the conductive portion approaches a second surface of the second surface side of the support portion in the sealing portion by half or greater of a thickness of the conductive portion, closer than a surface facing the circuit surface of the signal processing unit on the second surface of the conductive portion.

### Item 4

The current sensor according to item 1, wherein an outer surface area of the fourth corner is greater than an area of the third corner, and the support portion is bent to be coupled to the second terminal portion so as to approach an first surface of the first surface side of the conductive portion in the sealing portion.

### Item 5

The current sensor according to item 1, wherein an outer surface area of the fourth corner is greater than an area of the third corner, and the support portion is bent to be coupled to the second terminal portion, so that a surface of a portion coupled to the second terminal portion on the first surface of the support portion approaches the first surface of the first surface side of the conductive portion in the sealing portion by half or greater of a thickness of the support portion, closer than a surface that supports the signal processing unit on the first surface of the support portion.

### Item 6

The current sensor according to item 1, wherein an outer surface area of the second corner is greater than an outer surface area of the first corner, and the second corner is a chamfered surface.

### Item 7

The current sensor according to item 1, wherein an outer surface area of the fourth corner is greater than an outer surface area of the third corner, and the fourth corner is a chamfered surface.

### Item 8

The current sensor according to item 1, wherein at a predetermined minimum temperature, a linear expansion coefficient of the first lead frame or the second lead frame is greater than a linear expansion coefficient of mold resin composing the sealing portion.

### Item 9

The current sensor according to item 1, wherein when an outer surface area of the second corner is greater than an outer surface area of the first corner, either one of a width in a direction along the first surface of the conductive portion when the second corner is projected in a direction along the first end surface or a width in a direction along the first end surface when the second corner is projected in a direction along the first surface of the conductive portion is greater than 15 μm and shorter than a thickness of the conductive portion.

### Item 10

The current sensor according to item 9, wherein the sealing portion is composed of mold resin, and the mold resin contains filler with a diameter of 20 μm or greater, and the filler filling ratio is 60% or greater.

### Item 11

The current sensor according to item 1, wherein an outer surface area of the fourth corner is greater than an outer surface area of the third corner, and either one of a width in a direction along the second surface in the support portion when the fourth corner is projected in a direction along the second end surface or a width in a direction along the second end surface when the fourth corner is projected in a direction along the second surface of the support portion is greater than 15 μm and shorter than a thickness of the support portion.

### Item 12

The current sensor according to item 11, wherein the sealing portion is composed of mold resin, and the mold resin contains filler with a diameter of 20 μm or greater, and the filler filling ratio is 60% or greater.

### Item 13

The current sensor according to item 1, wherein the conductive portion is covered by mold resin composing the sealing portion, without an interface without any member other than the mold resin.

### Item 14

The current sensor according to item 1, wherein the first lead frame is thicker than the second lead frame.

### Item 15

The current sensor according to item 1, wherein:
the first terminal portion protrudes from a first side surface of the sealing portion, and the second terminal portion protrudes from a second side surface opposing the first side surface of the sealing portion in a first direction;
an outer surface area of the second corner is greater than an outer surface area of the first corner; and
when a distance between a first surface of the first surface side of the conductive portion and the first surface of the conductive portion in the sealing portion is set as t1, a width in a second direction intersecting the first direction along the first surface of the conductive portion of a portion facing the signal processing unit in the conductive portion is set as l1, a distance between the second surface of the conductive portion and the circuit surface of the signal processing unit is set as t2, and a width in the second direction along the circuit surface of the signal processing unit is set as l2, l1/t1>l2/t2 is satisfied.

### Item 16

The current sensor according to item 1, wherein:
the first terminal portion protrudes from a first side surface of the sealing portion, and the second terminal portion protrudes from a second side surface opposing the first side surface of the sealing portion in a first direction;
an outer surface area of the fourth corner is greater than an outer surface area of the third corner; and
when a distance between a second surface of the second surface side of the support portion and the second surface of the support portion in the sealing portion is set as t3, a width in a second direction intersecting the first direction along the second surface of the support portion of a portion supporting the signal processing unit in the support portion is set as l3, a distance between the second surface of the conductive portion and the circuit surface of the signal processing unit is set as t2, and a width in the second direction along the circuit surface of the signal processing unit is set as l2, l3/t3>l2/t2 is satisfied.

### Item 17

The current sensor according to any one of items 1 to 16, wherein:
the signal processing unit is an IC chip;
the at least one magnetoelectric conversion unit is a magnetoelectric conversion element separate from the IC chip; and
a magnetosensitive surface of the magnetoelectric conversion element protrudes from a surface facing the conductive portion of the IC chip.

### Item 18

The current sensor according to any one of items 1 to 16, wherein:
the signal processing unit is an IC chip;
the magnetoelectric conversion unit is built in the IC chip; and
a magnetosensitive surface of the magnetoelectric conversion unit does not protrude from a surface facing the conductive portion of the IC chip.

### EXPLANATION OF REFERENCES

10: current sensor; 20a, 20b: magnetoelectric conversion element; 22, 22a, 22b, 108: wire; 100: signal processing IC; 130: sealing portion; 140, 150: lead frame; 141: conductive portion; 141a, 141b: slit portion; 142: terminal portion; 142a, 142b, 152a: terminal; 144, 155: stepped portion; 152: terminal portion; 151, 154: support portion; 155: stepped portion; 1401: first corner; 1402: second corner; 1403, 1503: third corner; 1404, 1504: fourth corner; 1405: fifth corner; 1406: sixth corner; 1411: first portion; 1412: second portion; 1501: seventh corner; 1502: eighth corner.

What is claimed is:

1. A current sensor, comprising:
at least one magnetoelectric conversion element;
a first lead frame having a first terminal portion and a conductive portion coupled to the first terminal portion, wherein a measurement current measured by the at least one magnetoelectric conversion element flows through the first terminal portion and the conductive portion;
a signal processing IC that processes a signal output from the at least one magnetoelectric conversion element, arranged on a second surface side opposing a first surface of the conductive portion, having a circuit surface facing the second surface, with the at least one magnetoelectric conversion element arranged thereon; and
a sealing portion that seals the at least one magnetoelectric conversion element, the conductive portion and the signal processing IC,
wherein the conductive portion has a first corner between a first end surface opposing a side coupled to the first terminal portion and a second surface facing the signal processing IC, and a second corner between the first end surface and a first surface opposing the second surface facing the signal processing IC; and
wherein an outer surface area of the first corner is greater than an outer surface area of the second corner.

2. The current sensor according to claim 1, wherein the first corner is a chamfered surface.

3. The current sensor according to claim 1, wherein either one of a width in a direction along the second surface of the conductive portion when the first corner is projected in a direction along the first end surface or a width in a direction along the first end surface when the first corner is projected in a direction along the second surface of the conductive portion is greater than 15 μm and shorter than a thickness of the conductive portion.

4. The current sensor according to claim 1, wherein a width in a direction along the second surface of the conductive portion when the first corner is projected in a direction along the first end surface is longer than a width in a direction along the first end surface when the first corner is projected in a direction along the second surface of the conductive portion.

5. The current sensor according to claim 1, wherein:
the conductive portion has:
a first portion coupled to the first terminal portion; and
a second portion arranged facing the circuit surface of the signal processing IC, being shifted with respect to the first portion and coupled to the first portion in a direction away from the circuit surface of the signal processing IC in a thickness direction;
the second portion has a third corner between a second end surface on a side coupled to the first portion and a first surface opposing a second surface facing the circuit surface of the signal processing IC; and
an outer surface area of the third corner is greater than an outer surface area of a fourth corner between the second end surface of the second portion and a first surface of the first portion, which is on a side identical to the first surface of the second portion.

6. The current sensor according to claim 5, wherein the third corner is a chamfered surface.

7. The current sensor according to claim 5, wherein either one of a width in a direction along a first surface opposing the second surface of the conductive portion when the third corner is projected in a direction along the second end surface or a width in a direction along the second end surface when the third corner is projected in a direction along the first surface of the conductive portion is greater than 15 μm and shorter than a thickness of the conductive portion.

8. The current sensor according to claim 5, wherein a shift amount of the second portion with respect to the first portion is 0.6 times or less of a thickness of the conductive portion.

9. The current sensor according to claim 5, wherein the second end surface of the second portion has a sheared surface.

10. The current sensor according to claim 5, further comprising
a second lead frame, electrically insulated from the first lead frame, arranged to face the first terminal portion with the signal processing IC sandwiched therebetween in a planar view, having a second terminal portion electrically coupled to the signal processing IC and a support portion that supports, on a first surface, a surface opposing the circuit surface on a side of the conductive portion of the signal processing IC,
wherein the first portion has a fifth corner between a third end surface on a side coupled to the second portion and a second surface on a side identical to the second surface of the second portion; and
wherein an outer surface area of the fifth corner is greater than an outer surface area of a sixth corner between the third end surface of the first portion and the second surface of the second portion.

11. The current sensor according to claim 10, wherein the fifth corner is a chamfered surface.

12. The current sensor according to claim 10, wherein either one of a width in a direction along the second surface of the first portion when the fifth corner is projected in a direction along the third end surface or a width in a direction along the third end surface when the fifth corner is projected in a direction along the second surface of the first portion is greater than 15 μm and is shorter than a thickness of the conductive portion.

13. The current sensor according to claim 10, wherein:
the support portion has a seventh corner between the first surface that supports the signal processing IC and a fourth end surface on a side of the first terminal portion, and an eighth corner between a second surface opposing the first surface that supports the signal processing IC and the fourth end surface; and
an outer surface area of the seventh corner is greater than an outer surface area of the eighth corner.

14. The current sensor according to claim 3, wherein the sealing portion is composed of mold resin, and the mold resin contains filler with a diameter of 20 um or greater, and a filler filling ratio is 60% or greater.

15. The current sensor according to claim 1, wherein the at least one magnetoelectric conversion element protrudes from the circuit surface up to a position overlapping the conductive portion as viewed from a direction intersecting a thickness direction of the at least one magnetoelectric conversion element.

16. The current sensor according to claim 1, wherein:
the conductive portion has at least one slit portion; and
the at least one magnetoelectric conversion element is at least partially enclosed by the conductive portion by being respectively arranged inside the at least one slit portion in a planar view.

17. The current sensor according to claim 16, wherein the at least one magnetoelectric conversion element is respectively fixed on the circuit surface by die bonding inside the at least one slit portion, and is electrically coupled to the signal processing IC by wire bonding in a planar view.

18. The current sensor according to claim 17, wherein a magnetosensitive surface of the at least one magnetoelectric conversion element is arranged in a position overlapping a side surface with the at least one slit of the conductive portion provided thereon as viewed from a direction intersecting a thickness direction of the at least one magnetoelectric conversion element.

19. A current sensor, comprising:
at least one magnetoelectric conversion element;
a first lead frame having a first terminal portion and a conductive portion coupled to the first terminal portion, wherein a measurement current measured by the at least one magnetoelectric conversion element flows through the first terminal portion and the conductive portion;
a signal processing IC that processes a signal output from the at least one magnetoelectric conversion element, arranged on a second surface side opposing a first surface of the conductive portion, having a circuit surface facing the second surface, with the at least one magnetoelectric conversion element arranged thereon; and
a sealing portion that seals the at least one magnetoelectric conversion element, the conductive portion and the signal processing IC,
wherein the conductive portion has:
a first portion coupled to the first terminal portion; and
a second portion arranged facing the circuit surface of the signal processing IC, being shifted with respect to the first portion and coupled to the first portion in a direction away from the circuit surface of the signal processing IC in a thickness direction;
wherein the second portion has a third corner between a second end surface on a side coupled to the first portion and a first surface opposing a second surface facing the circuit surface of the signal processing IC; and
an outer surface area of the third corner is greater than an outer surface area of a fourth corner between the second end surface of the second portion and a first surface of the first portion, which is on a side identical to the first surface of the second portion.

20. A current sensor, comprising:
at least one magnetoelectric conversion element;
a first lead frame having a first terminal portion and a conductive portion coupled to the first terminal portion, wherein a measurement current measured by the at least one magnetoelectric conversion element flows through the first terminal portion and the conductive portion;
a signal processing IC that processes a signal output from the at least one magnetoelectric conversion element, having a circuit surface with the at least one magnetoelectric conversion element arranged thereon;
a second lead frame, electrically insulated from the first lead frame, arranged to face the first terminal portion with the signal processing IC sandwiched therebetween in a planar view, having a second terminal portion electrically coupled to the signal processing IC and a support portion that supports the signal processing IC on a first surface; and
a sealing portion that seals the at least one magnetoelectric conversion element, the conductive portion, the signal processing IC and the support portion,
wherein the conductive portion includes a first sheared surface that is a step or an end surface with a sheared surface, on a side closer to the first terminal portion than the signal processing IC in a planar view and facing toward a side of the second terminal portion, with an outer surface area of a fifth corner closer to a second surface opposing the first surface of the support portion being greater than an outer surface area of a sixth corner further from the second surface at a corner of the first sheared surface.
